(19) United States
(12) Patent Application Publication
(10) Pub. No.: US 2026/0165212 A1
(43) Pub. Date: Jun. 11, 2026

(54) SEMICONDUCTOR DEVICE

(71) Applicant: AOI ELECTRONICS CO., LTD., Takamatsu-shi, Kagawa (JP)

(72) Inventor: Takashi SUZUKI, Kagawa (JP)

(21) Appl. No.: 18/705,708

(22) PCT Filed: Sep. 5, 2022
(86) PCT No.: PCT/JP2022/033288

§ 371 Date: Apr. 29, 2024

(30) Foreign Application Priority Data
Nov. 2, 2021 (JP) 2021-179698

(51) Int. Cl. H10W 90/10; H10W 70/09; H10W 70/40; H10W 70/60; H10W 90/00

(52) U.S. Cl. CPC H10W 90/10; H10W 70/09; H10W 70/417; H10W 70/614; H10W 90/736; H10W 90/811

(57) ABSTRACT

A semiconductor device 1 includes die pads 5 and 6, semiconductor chips 2 and 3, and an insulator portion 28 configured to seal them. The semiconductor chip 2 has a source electrode 2S formed on a side of a front surface and a drain electrode 2D formed on a side of a back surface, and is mounted on the die pad 5 such that the drain electrode 2D faces the die pad 5. The semiconductor chip 3 has a source electrode 3S formed on a side of a front surface and a drain electrode 3D formed on a side of a back surface, and is mounted on the die pad 6 such that the source electrode 3S faces the die pad 6. Then, a wiring 26DS configured to electrically connect the source electrode 2S of the semiconductor chip 2 and the drain electrode 3D of the semiconductor chip 3 is formed in the insulator portion 28.

### TECHNICAL FIELD

The present invention relates to a semiconductor device, and can be favorably used for, for example, a semiconductor device in which a semiconductor chip including a field effect transistor for high side switch and a semiconductor chip including a field effect transistor for low side switch are sealed together.

### BACKGROUND ART

As a power supply circuit, for example, a DC-DC converter has a configuration in which a power MOSFET for high side switch and a power MOSFET for low side switch are connected in series. Therefore, a semiconductor device in which a semiconductor chip having a power MOSFET for high side switch formed therein and a semiconductor chip having a power MOSFET for low side switch formed therein are packaged together has been used.

Japanese Unexamined Patent Application Publication No. 2010-50286 (Patent Document 1) discloses a technique related to a semiconductor device in which a three-terminal semiconductor chip having a vertical MOS transistor formed therein is sealed with a resin.

Japanese Unexamined Patent Application Publication No. 2013-219324 (Patent Document 2) discloses a technique related to a semiconductor package including a semiconductor chip in which a source electrode and a gate electrode are formed on a front surface side and a drain electrode is formed on a back surface side.

Japanese Unexamined Patent Application Publication No. 2019-102765 (Patent Document 3) discloses a technique related to a semiconductor package in which a first semiconductor chip including a high side switching element and a second semiconductor chip including a low side switching element are sealed with a molding material.

### RELATED ART DOCUMENTS

### Patent Documents

Patent Document 1: Japanese Unexamined Patent Application Publication No. 2010-50286

Patent Document 2: Japanese Unexamined Patent Application Publication No. 2013-219324

Patent Document 3: Japanese Unexamined Patent Application Publication No. 2019-102765

### SUMMARY OF THE INVENTION

### Problems to be Solved by the Invention

In a semiconductor device in which a semiconductor chip having a power MOSFET for high side switch formed therein and a semiconductor chip having a power MOSFET for low side switch formed therein are packaged together, the power MOSFET for high side switch and the power MOSFET for low side switch are connected in series in the semiconductor device in some cases. Even such a semiconductor device is desired to be made as small as possible in size.

### Means for Solving the Problem

According to an embodiment, a semiconductor device includes a first chip mounting portion, a second chip mounting portion, a first semiconductor chip mounted on the first chip mounting portion, a second semiconductor chip mounted on the second chip mounting portion, and an insulator portion configured to seal them. The first semiconductor chip has a source electrode formed on a side of a main surface and a drain electrode formed on a side of a back surface opposite to the main surface, and is mounted on the first chip mounting portion such that the drain electrode faces the first chip mounting portion. The second semiconductor chip has a source electrode formed on a side of a main surface and a drain electrode formed on a side of a back surface opposite to the main surface, and is mounted on the second chip mounting portion such that the source electrode faces the second chip mounting portion. Then, a first wiring configured to electrically connect the source electrode of the first semiconductor chip and the drain electrode of the second semiconductor chip is formed in the insulator portion.

### Effects of the Invention

According to an embodiment, it is possible to reduce the size of the semiconductor device.

### BRIEF DESCRIPTIONS OF THE DRAWINGS

FIG. 1 is a circuit diagram showing a circuit configuration of a semiconductor device according to the first embodiment.

FIG. 2 is a top view of the semiconductor device according to the first embodiment.

FIG. 3 is a bottom view of the semiconductor device according to the first embodiment.

FIG. 4 is a transparent plan view of the semiconductor device according to the first embodiment.

FIG. 5 is a transparent plan view of the semiconductor device according to the first embodiment.

FIG. 6 is a transparent plan view of the semiconductor device according to the first embodiment.

FIG. 7 is a transparent plan view of the semiconductor device according to the first embodiment.

FIG. 8 is a cross-sectional view of the semiconductor device according to the first embodiment.

FIG. 9 is a cross-sectional view of the semiconductor device according to the first embodiment.

FIG. 10 is a cross-sectional view of the semiconductor device according to the first embodiment.

FIG. 11 is a top view of semiconductor chips.

FIG. 12 is a bottom view of the semiconductor chips.

FIG. 13 is a cross-sectional view showing a manufacturing step of the semiconductor device according to the first embodiment.

FIG. 14 is a cross-sectional view showing the same manufacturing step of the semiconductor device as FIG. 13.

FIG. 15 is a cross-sectional view showing the manufacturing step of the semiconductor device subsequent to FIG. 13.

FIG. 16 is a cross-sectional view showing the same manufacturing step of the semiconductor device as FIG. 15.

FIG. 17 is a cross-sectional view showing the manufacturing step of the semiconductor device subsequent to FIG. 16.

FIG. 18 is a cross-sectional view showing the manufacturing step of the semiconductor device subsequent to FIG. 17.

FIG. 19 is a cross-sectional view showing the same manufacturing step of the semiconductor device as FIG. 18.

FIG. 20 is a cross-sectional view showing the manufacturing step of the semiconductor device subsequent to FIG. 18.

FIG. 21 is cross-sectional view showing the same manufacturing step of the semiconductor device as FIG. 20.

FIG. 22 is a cross-sectional view showing the manufacturing step of the semiconductor device subsequent to FIG. 20.

FIG. 23 is a cross-sectional view showing the same manufacturing step of the semiconductor device as FIG. 22.

FIG. 24 is a cross-sectional view showing the manufacturing step of the semiconductor device subsequent to FIG. 22.

FIG. 25 is a cross-sectional view showing the same manufacturing step of the semiconductor device as FIG. 24.

FIG. 26 is a cross-sectional view showing the manufacturing step of the semiconductor device subsequent to FIG. 24.

FIG. 27 is a cross-sectional view showing the same manufacturing step of the semiconductor device as FIG. 26.

FIG. 28 is a cross-sectional view showing the manufacturing step of the semiconductor device subsequent to FIG. 26.

FIG. 29 is a cross-sectional view showing the same manufacturing step of the semiconductor device as FIG. 28.

FIG. 30 is a circuit diagram showing a circuit configuration of a semiconductor device according to the second embodiment.

FIG. 31 is a transparent plan view of the semiconductor device according to the second embodiment.

FIG. 32 is a transparent plan view of the semiconductor device according to the second embodiment.

FIG. 33 is a transparent plan view of the semiconductor device according to the second embodiment.

FIG. 34 is a bottom view of the semiconductor device according to the second embodiment.

FIG. 35 is a cross-sectional view of the semiconductor device according to the second embodiment.

FIG. 36 is a cross-sectional view of the semiconductor device according to the second embodiment.

FIG. 37 is a cross-sectional view of the semiconductor device according to the second embodiment.

FIG. 38 is a cross-sectional view of the semiconductor device according to the second embodiment.

FIG. 39 is a cross-sectional view of the semiconductor device according to the second embodiment.

FIG. 40 is a cross-sectional view showing a manufacturing step of the semiconductor device according to the second embodiment.

FIG. 41 is a cross-sectional view showing the same manufacturing step of the semiconductor device as FIG. 40.

FIG. 42 is a cross-sectional view showing the manufacturing step of the semiconductor device subsequent to FIG. 40.

FIG. 43 is a cross-sectional view showing the same manufacturing step of the semiconductor device as FIG. 42.

FIG. 44 is a cross-sectional view showing the manufacturing step of the semiconductor device subsequent to FIG. 42.

FIG. 45 is a cross-sectional view showing the same manufacturing step of the semiconductor device as FIG. 44.

FIG. 46 is a cross-sectional view showing the manufacturing step of the semiconductor device subsequent to FIG. 44.

FIG. 47 is a cross-sectional view showing the same manufacturing step of the semiconductor device as FIG. 46.

FIG. 48 is a cross-sectional view showing the manufacturing step of the semiconductor device subsequent to FIG. 46.

FIG. 49 is a cross-sectional view showing the same manufacturing step of the semiconductor device as FIG. 48.

FIG. 50 is a cross-sectional view showing the manufacturing step of the semiconductor device subsequent to FIG. 48.

FIG. 51 is a cross-sectional view showing the same manufacturing step of the semiconductor device as FIG. 50.

FIG. 52 is a cross-sectional view showing the manufacturing step of the semiconductor device subsequent to FIG. 50.

FIG. 53 is a cross-sectional view showing the same manufacturing step of the semiconductor device as FIG. 52.

FIG. 54 is a cross-sectional view of a semiconductor device according to the third embodiment.

FIG. 55 is a cross-sectional view of the semiconductor device according to the third embodiment.

FIG. 56 is a cross-sectional view of the semiconductor device according to the third embodiment.

FIG. 57 is a cross-sectional view of the semiconductor device according to the third embodiment.

FIG. 58 is a cross-sectional view of the semiconductor device according to the third embodiment.

FIG. 59 is a cross-sectional view showing a manufacturing step of the semiconductor device according to the third embodiment.

FIG. 60 is a cross-sectional view showing the same manufacturing step of the semiconductor device as FIG. 59.

FIG. 61 is a cross-sectional view showing the manufacturing step of the semiconductor device subsequent to FIG. 59.

FIG. 62 is cross-sectional view showing the same manufacturing step of the semiconductor device as FIG. 61.

FIG. 63 is a cross-sectional view showing the manufacturing step of the semiconductor device subsequent to FIG. 61.

FIG. 64 is a cross-sectional view showing the same manufacturing step of the semiconductor device as FIG. 63.

FIG. 65 is a cross-sectional view showing the manufacturing step of the semiconductor device subsequent to FIG. 63.

FIG. 66 is a cross-sectional view showing the same manufacturing step of the semiconductor device as FIG. 65.

FIG. 67 is a cross-sectional view of a semiconductor device according to the fourth embodiment.

FIG. 68 is a cross-sectional view of the semiconductor device according to the fourth embodiment.

FIG. 69 is a cross-sectional view of the semiconductor device according to the fourth embodiment.

FIG. 70 is a cross-sectional view of the semiconductor device according to the fourth embodiment.

FIG. 71 is a cross-sectional view of the semiconductor device according to the fourth embodiment.

FIG. 72 is a transparent plan view of the semiconductor device according to the fourth embodiment.

FIG. 73 is a transparent plan view of the semiconductor device according to the fourth embodiment.

FIG. 74 is a cross-sectional view showing a manufacturing step of the semiconductor device according to the fourth embodiment.

FIG. 75 is a cross-sectional view showing the same manufacturing step of the semiconductor device as FIG. 74.

FIG. 76 is a cross-sectional view showing the same manufacturing step of the semiconductor device as FIG. 74.

FIG. 77 is a cross-sectional view showing the manufacturing step of the semiconductor device subsequent to FIG. 74.

FIG. 78 is a cross-sectional view showing the same manufacturing step of the semiconductor device as FIG. 77.

FIG. 79 is a cross-sectional view showing the same manufacturing step of the semiconductor device as FIG. 77.

FIG. 80 is a cross-sectional view showing the manufacturing step of the semiconductor device subsequent to FIG. 77.

FIG. 81 is a cross-sectional view showing the same manufacturing step of the semiconductor device as FIG. 80.

FIG. 82 is a cross-sectional view showing the same manufacturing step of the semiconductor device as FIG. 80.

FIG. 83 is a cross-sectional view of a semiconductor device according to the fifth embodiment.

FIG. 84 is a cross-sectional view of the semiconductor device according to the fifth embodiment.

FIG. 85 is a cross-sectional view showing a manufacturing step of a semiconductor device according to the sixth embodiment.

FIG. 86 is a cross-sectional view showing the same manufacturing step of the semiconductor device as FIG. 85.

FIG. 87 is a cross-sectional view showing the same manufacturing step of the semiconductor device as FIG. 85.

FIG. 88 is a cross-sectional view showing the manufacturing step of the semiconductor device subsequent to FIG. 85.

FIG. 89 is a cross-sectional view showing the same manufacturing step of the semiconductor device as FIG. 88.

FIG. 90 is a cross-sectional view showing the same manufacturing step of the semiconductor device as FIG. 88.

FIG. 91 is a cross-sectional view showing the manufacturing step of the semiconductor device subsequent to FIG. 88.

FIG. 92 is a cross-sectional view showing the same manufacturing step of the semiconductor device as FIG. 91.

FIG. 93 is a cross-sectional view showing the same manufacturing step of the semiconductor device as FIG. 91.

FIG. 94 is a cross-sectional view showing the manufacturing step of the semiconductor device subsequent to FIG. 91.

FIG. 95 is a cross-sectional view showing the same manufacturing step of the semiconductor device as FIG. 94.

FIG. 96 is a cross-sectional view showing the same manufacturing step of the semiconductor device as FIG. 94.

FIG. 97 is a cross-sectional view showing the manufacturing step of the semiconductor device subsequent to FIG. 94.

FIG. 98 is a cross-sectional view showing the same manufacturing step of the semiconductor device as FIG. 97.

FIG. 99 is a cross-sectional view showing the same manufacturing step of the semiconductor device as FIG. 97.

FIG. 100 is a cross-sectional view showing a manufacturing step of a semiconductor device according to the seventh embodiment.

FIG. 101 is a cross-sectional view showing the same manufacturing step of the semiconductor device as FIG. 100.

FIG. 102 is a cross-sectional view showing the same manufacturing step of the semiconductor device as FIG. 100.

FIG. 103 is a cross-sectional view showing the manufacturing step of the semiconductor device subsequent to FIG. 100.

FIG. 104 is a cross-sectional view showing the same manufacturing step of the semiconductor device as FIG. 103.

FIG. 105 is a cross-sectional view showing the same manufacturing step of the semiconductor device as FIG. 103.

FIG. 106 is a cross-sectional view showing the manufacturing step of the semiconductor device subsequent to FIG. 103.

FIG. 107 is a cross-sectional view showing the same manufacturing step of the semiconductor device as FIG. 106.

FIG. 108 is a cross-sectional view showing the same manufacturing step of the semiconductor device as FIG. 106.

FIG. 109 is a cross-sectional view showing the manufacturing step of the semiconductor device subsequent to FIG. 106.

FIG. 110 is cross-sectional view showing the same manufacturing step of the semiconductor device as FIG. 109.

FIG. 111 is a cross-sectional view showing the same manufacturing step of the semiconductor device as FIG. 109.

FIG. 112 is a cross-sectional view showing the manufacturing step of the semiconductor device subsequent to FIG. 109.

FIG. 113 is a cross-sectional view showing the same manufacturing step of the semiconductor device as FIG. 112.

FIG. 114 is a cross-sectional view showing the same manufacturing step of the semiconductor device as FIG. 112.

### DETAILED DESCRIPTION OF PREFERRED EMBODIMENTS

Hereinafter, embodiments will be described in detail with reference to drawings. Note that the members having the same function are denoted by the same reference characters throughout the drawings for describing the embodiments, and the repetitive description thereof will be omitted. Further, in the following embodiments, the description of the same or similar part will not be repeated in principle unless particularly required.

Also, in this application, a field effect transistor is referred to as a MOSFET (Metal Oxide Semiconductor Field Effect Transistor), but this does not mean that a non-oxide film is excluded as a gate insulating film.

### First Embodiment

### Circuit Configuration

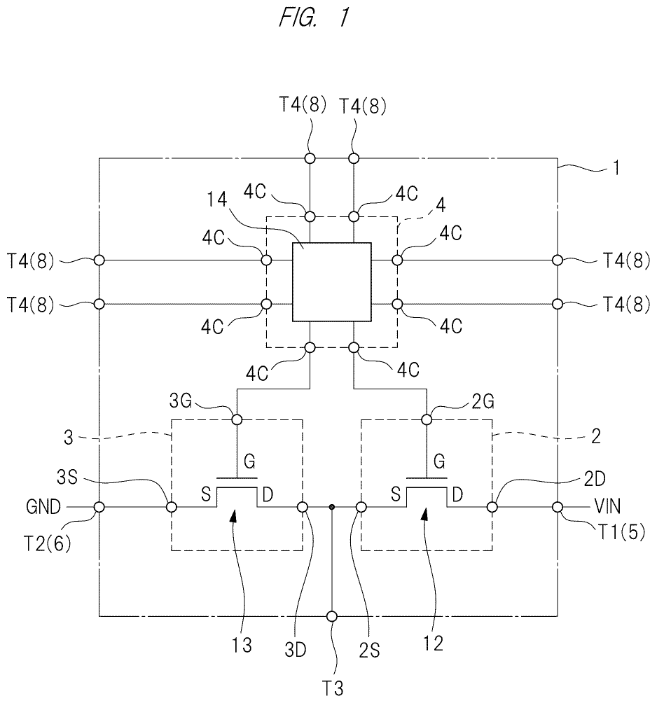

FIG. 1 is a circuit diagram showing a circuit configuration of a semiconductor device (semiconductor package) 1 according to an embodiment of the present invention. The semiconductor device 1 can be used for, for example, a non-insulated DC-DC converter or an inverter. In FIG. 1, the part surrounded by a dashed-dotted line denoted by reference numeral 1 is a circuit formed in the semiconductor device 1. In this part, the part surrounded by a dotted line denoted by reference numeral 2 is the part formed in a semiconductor chip 2, the part surrounded by a dotted line denoted by reference numeral 3 is the part formed in a semiconductor chip 3, and the part surrounded by a dotted line denoted by reference numeral 4 is the part formed in a semiconductor chip 4.

As shown in FIG. 1, the semiconductor device 1 includes the semiconductor chips 2, 3, and 4, and these three semiconductor chips 2, 3, and 4 are sealed in one package to form the semiconductor device 1. A power MOSFET 12 is formed in the semiconductor chip 2, a power MOSFET 13 is formed in the semiconductor chip 3, and a control circuit 14 is formed in the semiconductor chip 4. As the power MOSFET, for example, a trench gate MOSFET can be used.

The semiconductor chip 2 has a source electrode 2S electrically connected to a source (S) of the power MOSFET 12 formed in the semiconductor chip 2, a drain electrode 2D electrically connected to a drain (D) of the power MOSFET 12 formed in the semiconductor chip 2, and a gate electrode 2G electrically connected to a gate (G) of the power MOSFET 12 formed in the semiconductor chip 2. Also, the semiconductor chip 3 has a source electrode 3S electrically connected to a source (S) of the power MOSFET 13 formed in the semiconductor chip 3, a drain electrode 3D electrically connected to a drain (D) of the power MOSFET 13 formed in the semiconductor chip 3, and a gate electrode 3G electrically connected to a gate (G) of the power MOSFET 13 formed in the semiconductor chip 3. Further, the semiconductor chip 4 has a plurality of electrodes 4C electrically connected to the control circuit 14 formed in the semiconductor chip 4.

The power MOSFET 12 is a field effect transistor for high side switch (high potential side switch), and the power MOSFET 13 is a field effect transistor for low side switch (low potential side switch).

The power MOSFET 12 and the power MOSFET 13 are connected in series between a terminal T1 and a terminal T2, the drain (D) of the power MOSFET 12 is connected to the terminal T1, the source (S) of the power MOSFET 12 is connected to the drain (D) of the power MOSFET 13, and the source (S) of the power MOSFET 13 is connected to the terminal T2. Specifically, the drain electrode 2D of the semiconductor chip 2 is electrically connected to the terminal T1, the source electrode 2S of the semiconductor chip 2 is electrically connected to the drain electrode 3D of the semiconductor chip 3, and the source electrode 3S of the semiconductor chip 3 is electrically connected to the terminal T2. The terminal T3 is electrically connected to both the source electrode 2S of the semiconductor chip 2 and the drain electrode 3D of the semiconductor chip 3.

The terminals T1, T2, and T3 are external terminals (external connection terminals) of the semiconductor device 1. A power supply potential (VIN) is supplied to the terminal Tl from an external power supply of the semiconductor device 1 or the like. A reference potential lower than the power supply potential, for example, a ground potential (GND) is supplied to the terminal T2. The terminal T3 is an output terminal. The terminal T3 is connected to, for example, a load provided outside the semiconductor device 1.

The gate electrode 2G of the semiconductor chip 2 is electrically connected to the electrode 4C of the semiconductor chip 4, and the gate electrode 3G of the semiconductor chip 3 is electrically connected to another electrode 4C of the semiconductor chip 4. The control circuit 14 formed in the semiconductor chip 4 includes a circuit (drive circuit) that controls the operation of the power MOSFETs 12 and 13. The control circuit 14 can control the operation of the power MOSFETs 12 and 13 by controlling the gate voltage supplied from the electrodes 4C of the semiconductor chip 4 to the gate electrodes 2G and 3G of the semiconductor chips 2 and 3. The other electrodes 4C of the semiconductor chip 4 are electrically connected to terminals T4. The terminal T4 is also an external terminal of the semiconductor device 1, and the control circuit 14 can be connected to a circuit outside the semiconductor device 1 through the terminal T4.

### Structure of Semiconductor Device

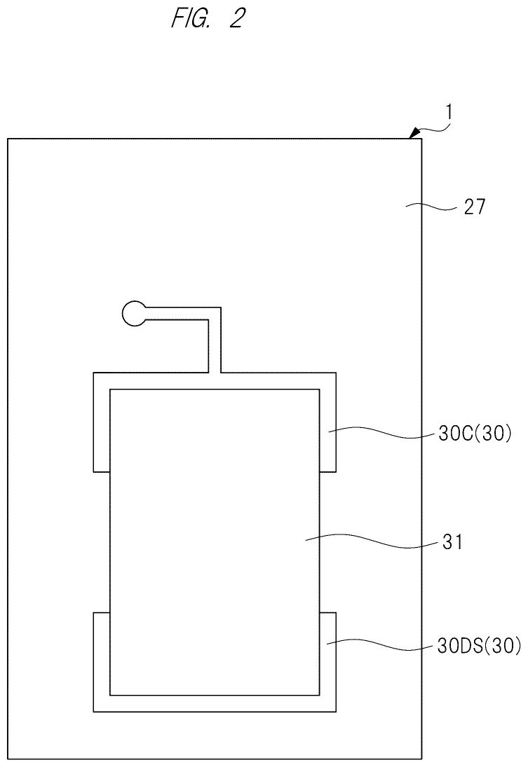

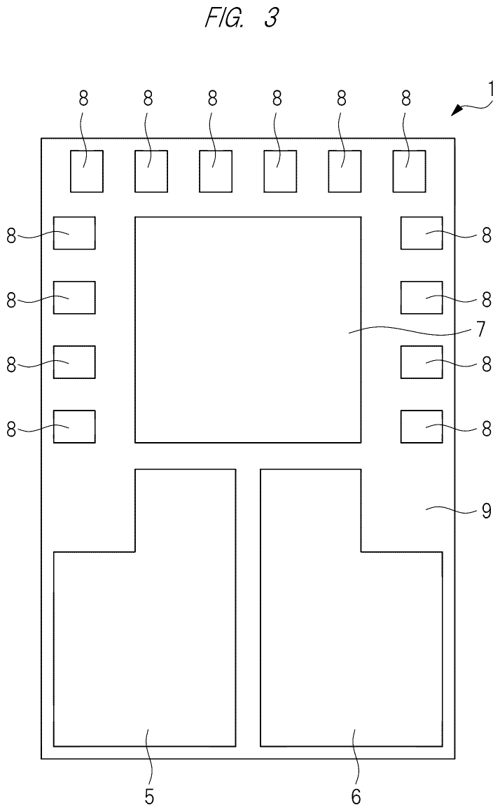

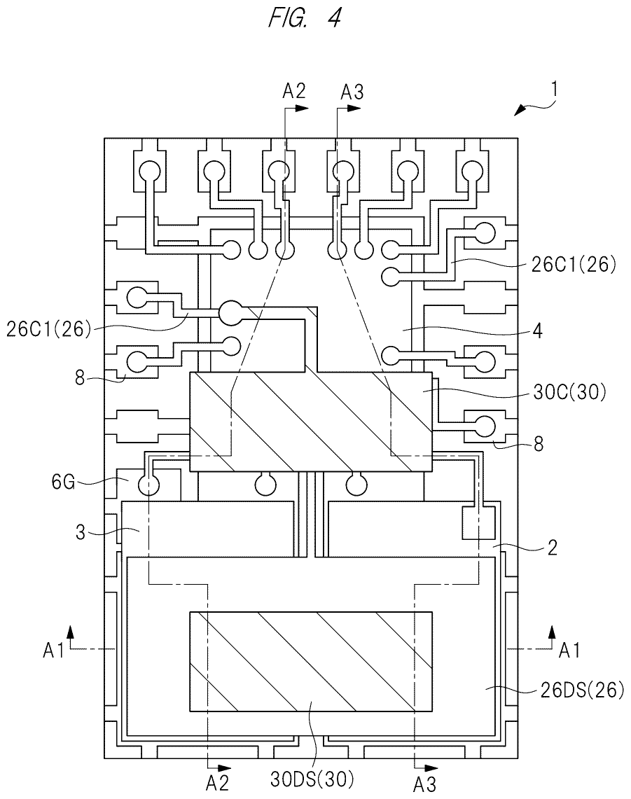

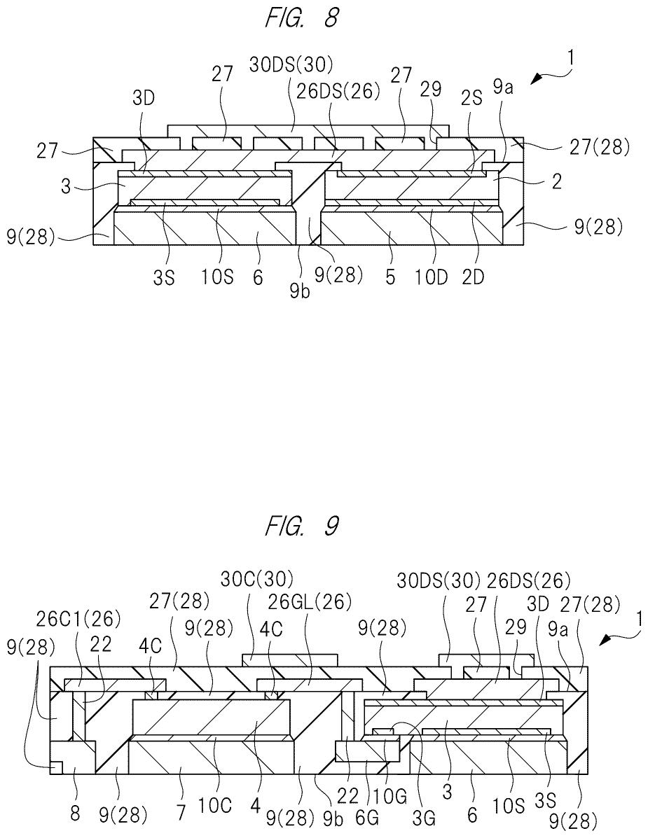

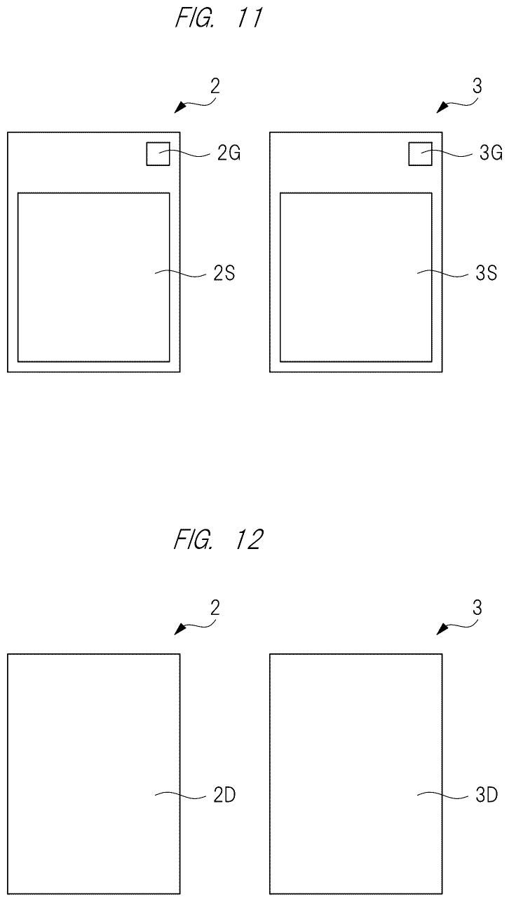

FIG. 2 is a top view of the semiconductor device 1 according to the present embodiment, and FIG. 3 is a bottom view (back view) of the semiconductor device 1 according to the present embodiment. FIG. 4 to FIG. 7 are transparent plan views of the semiconductor device 1 according to the present embodiment, and FIG. 8 to FIG. 10 are cross-sectional views of the semiconductor device 1 according to the present embodiment. FIG. 11 is a top view of the semiconductor chips 2 and 3 used in the semiconductor device 1 according to the present embodiment, and FIG. 12 is a bottom view (back view) of the semiconductor chips 2 and 3 used in the semiconductor device 1 according to the present embodiment.

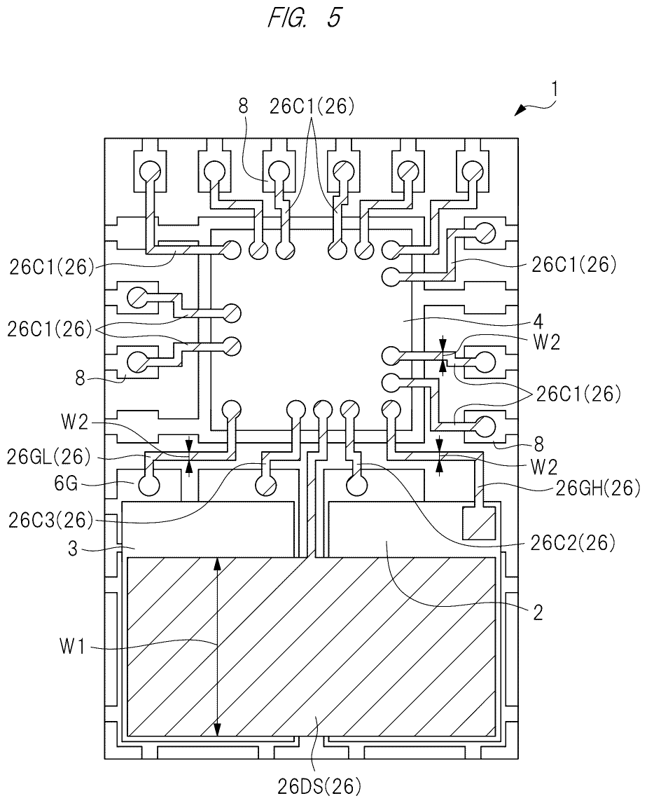

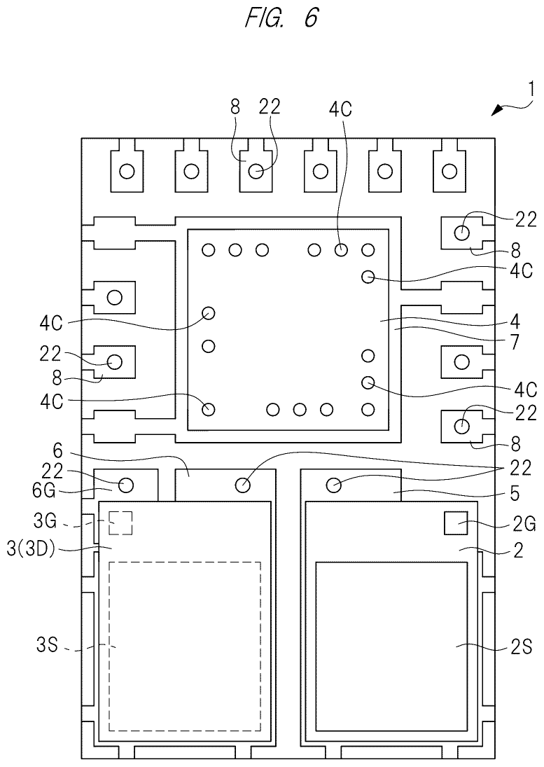

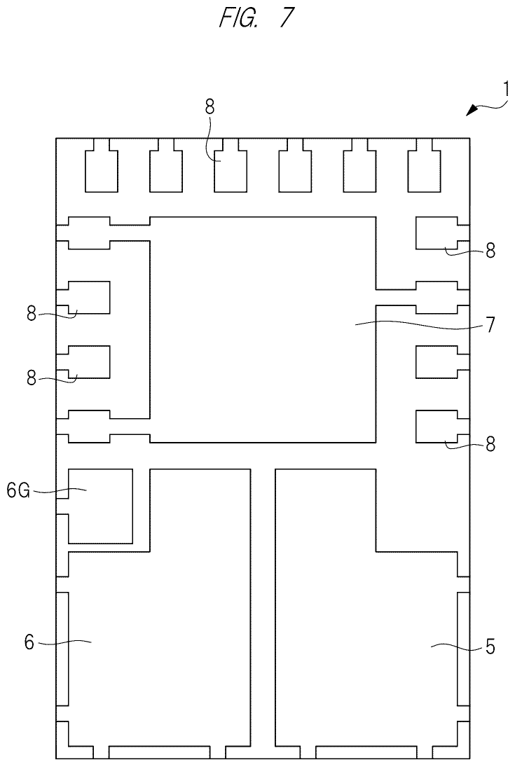

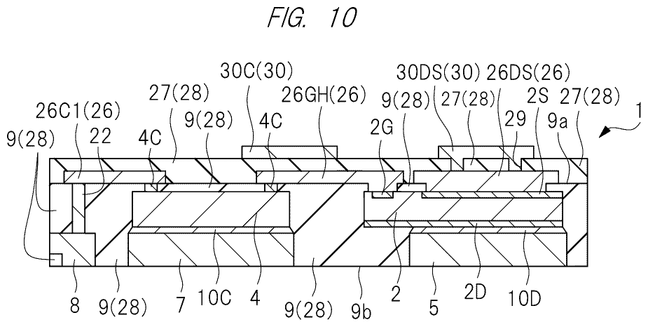

Note that FIG. 2 shows a state in which an electronic component 31 is mounted on the semiconductor device 1. Also, FIG. 4 is a transparent plan view showing the semiconductor device 1 seen through components made of an insulator (insulating layer 27 and sealing portion 9). Also, FIG. 5 is a transparent plan view showing the semiconductor device 1 seen further through wirings 30 (wirings 30DS and 30C) in FIG. 4. In addition, FIG. 6 is a transparent plan view showing the semiconductor device 1 seen further through wirings 26 (wirings 26DS, 26GH, 26GL, 26C1, 26C2, and 26C3) in FIG. 5. Note that what can be actually seen in FIG. 6 is the drain electrode 3D of the semiconductor chip 3, but the planar positions of the gate electrode 3G and the source electrode 3S in the semiconductor chip 3 are indicated by dotted lines for ease of understanding. Also, FIG. 7 is a transparent plan view showing the semiconductor device 1 seen further through the semiconductor chips 2, 3, and 4 and a plug portion 22 in FIG. 6. Further, FIG. 8 is a cross-sectional view of the semiconductor device 1 taken at the position of the line A1-A1 shown in FIG. 4, FIG. 9 is a cross-sectional view of the semiconductor device 1 taken at the position of the line A2-A2 shown in FIG. 4, and FIG. 10 is a cross-sectional view of the semiconductor device 1 taken at the position of the line A3-A3 shown in FIG. 4.

In the present embodiment, as described above, the semiconductor chip 2 in which the power MOSFET 12 for high side switch is formed, the semiconductor chip 3 in which the power MOSFET 13 for low side switch is formed, and the semiconductor chip 4 in which the control circuit 14 is formed are packaged together to form one semiconductor device 1. Here, an example in which a QFN (Quad Flat Non-leaded package) surface-mount semiconductor package is applied as the semiconductor device 1 will be described. The specific configuration of the semiconductor device 1 according to the present embodiment will be described below with reference to FIG. 2 to FIG. 12.

The semiconductor device 1 according to the present embodiment includes die pads (chip mounting portions) 5, 6, and 7, the semiconductor chips 2, 3, and 4 mounted on the die pads 5, 6, and 7, a plurality of leads 8, and the sealing portion (sealing resin portion) 9 configured to seal them.

The sealing portion 9 is made of, for example, an insulating resin material such as a thermosetting resin. The sealing portion 9 has an upper surface 9a which is one main surface, a lower surface 9b which is the main surface on the side opposite to the upper surface 9a, and four side surfaces which connect the upper surface 9a and the lower surface 9b.

The plurality of leads 8 in the semiconductor device 1 are arranged along the outer periphery of the semiconductor device 1, and the lower surface of each lead 8 is exposed on the lower surface 9b of the sealing portion 9. Further, on the lower surface 9b of the sealing portion 9, the lower surfaces of the die pads 5, 6, and 7 are also exposed. The die pads 5, 6, and 7 are spaced apart from each other, and the sealing portion 9 fills the space between the die pads 5, 6, and 7.

Each of the semiconductor chips 2, 3, and 4 has a front surface which is one main surface and a back surface which is the main surface on the side opposite thereto, FIG. 11 shows the front surface side of each of the semiconductor chips 2 and 3, and FIG. 12 shows the back surface side of each of the semiconductor chips 2 and 3.

In the semiconductor chip 2, the source electrode 2S and the gate electrode 2G are formed on the front surface side of the semiconductor chip 2, and the drain electrode 2D is formed on the back surface side of the semiconductor chip 2. Namely, in the semiconductor chip 2, the source electrode 2S and the gate electrode 2G, and the drain electrode 2D are formed on the surfaces on the sides opposite to each other. Similarly, in the semiconductor chip 3, the source electrode 3S and the gate electrode 3G are formed on the front surface side of the semiconductor chip 3, and the drain electrode 3D is formed on the back surface side of the semiconductor chip 3. Namely, in the semiconductor chip 3, the source electrode 3S and the gate electrode 3G, and the drain electrode 3D are formed on the surfaces on the sides opposite to each other.

In the semiconductor chip 4, the plurality of electrodes 4C are formed on the front surface side of the semiconductor chip 4. The electrode 4C is a connection electrode formed on the pad electrode of the semiconductor chip 4, and is, for example, a columnar electrode.

In the semiconductor device 1 according to the present embodiment, the semiconductor chip 2 and the semiconductor chip 3 are mounted upside down (in a vertical direction) with each other. Namely, the front surface side of the semiconductor chip 2 faces upward and the back surface side thereof faces downward (toward the die pad 5), whereas the back surface side of the semiconductor chip 3 faces upward and the front surface side thereof faces downward (toward the die pad 6).

Specifically, the semiconductor chip 2 is bonded to the upper surface of the die pad 5 by a conductive bonding material 10D such that the source electrode 2S and the gate electrode 2G face upward and the drain electrode 2D faces the upper surface of the die pad 5. In this way, the drain electrode 2D of the semiconductor chip 2 and the die pad 5 are electrically connected via the conductive bonding material 10D. On the other hand, the semiconductor chip 3 is bonded to the upper surface of the die pad 6 by a conductive bonding material 10S such that the drain electrode 3D faces upward and the source electrode 3S faces the upper surface of the die pad 6. In this way, the source electrode 3S of the semiconductor chip 3 and the die pad 6 are electrically connected via the conductive bonding material 10S. The gate electrode 3G of the semiconductor chip 3 is electrically connected to a gate connection conductor portion 6G. The gate electrode 3G of the semiconductor chip 3 is electrically connected to the gate connection conductor portion 6G via a conductive bonding material 10G. It is preferable that the gate connection conductor portion 6G is not exposed on the lower surface 9b of the sealing portion 9. For example, the gate connection conductor portion 6G is made thinner than the die pads 5, 6, and 7 and the leads 8 by performing half-etching on the lower surface side of the gate connection conductor portion 6G, whereby the lower surfaces of the die pads 5, 6, and 7 and the leads 8 can be exposed on the lower surface 9b of the sealing portion 9 without exposing the gate connection conductor portion 6G.

The semiconductor chip 4 is bonded to the upper surface of the die pad 7 by an insulating or conductive bonding material 10C such that the electrode 4C faces upward and the back surface of the semiconductor chip 4 faces the upper surface of the die pad 7.

The die pads 5, 6, and 7, the gate connection conductor portion 6G, and the plurality of leads 8 are made of a conductor, preferably a metal material such as copper (Cu) or a copper alloy (for example, a copper alloy containing nickel), and a plating film (for example, a nickel plating film) can be formed on the surface thereof as necessary. Furthermore, if the die pads 5, 6, and 7, the gate connection conductor portion 6G, and the plurality of leads 8 are formed of one lead frame, the semiconductor device 1 can be manufactured more easily using the lead frame because there is no need to combine a plurality of members.

The source electrode 2S and the gate electrode 2G of the semiconductor chip 2 and the plurality of electrodes 4C of the semiconductor chip 4 are exposed on the upper surface of the sealing portion 9. For example, on the source electrode 2S of the semiconductor chip 2, an opening is provided in the sealing portion 9 so as to expose the source electrode 2S. Further, on the gate electrode 2G of the semiconductor chip 2, an opening is provided in the sealing portion 9 so as to expose the gate electrode 2G.

The wirings (wiring layer, patterned conductor layer) 26 are formed on the upper surface of the sealing portion 9. The wirings 26 include the wirings 26DS, 26GH, 26GL, 26C1, 26C2, and 26C3. The wirings 26DS, 26GH, 26GL, 26C1, 26C2, and 26C3 included in the wirings 26 are formed in the same layer. Also, the conductive plug portion 22 is formed on each of the die pads 5 and 6, the gate connection conductor portion 6G, and the lead 8. The plug portion 22 is made of a metal material such as copper (Cu), and is formed in a hole provided in the sealing portion 9. The plug portion 22 is provided to electrically connect the wiring 26 on the plug portion 22 and the conductor (die pad 5, die pad 6, gate connection conductor portion 6G, or lead 8) under the plug portion 22.

The wiring 26DS is a wiring for electrically connecting the source electrode 2S of the semiconductor chip 2 and the drain electrode 3D of the semiconductor chip 3. The wiring 26DS integrally includes a part which is located on the source electrode 2S of the semiconductor chip 2 and is electrically connected to the source electrode 2S, a part which is located on the drain electrode 3D of the semiconductor chip 3 and is electrically connected to the drain electrode 3D, and a part configured to connect them.

The wiring 26GL is a wiring for electrically connecting the gate electrode 3G of the semiconductor chip 3 and the electrode 4C of the semiconductor chip 4. One end of the wiring 26GL is located on the plug portion 22 provided on the gate connection conductor portion 6G and is electrically connected to the plug portion 22, and the other end of the wiring 26GL is located on the electrode 4C of the semiconductor chip 4 and is electrically connected to the electrode 4C. In this way, the gate electrode 3G of the semiconductor chip 3 and the electrode 4C of the semiconductor chip 4 are electrically connected to each other via the conductive bonding material 10G, the gate connection conductor portion 6G, the plug portion 22 (the plug portion 22 formed on the gate connection conductor portion 6G), and the wiring 26GL.

The wiring 26GH is a wiring for electrically connecting the gate electrode 2G of the semiconductor chip 2 and the electrode 4C of the semiconductor chip 4. One end of the wiring 26GH is located on the gate electrode 2G of the semiconductor chip 2 and is electrically connected to the gate electrode 2G, and the other end of the wiring 26GH is located on the electrode 4C of the semiconductor chip 4 and is electrically connected to the electrode 4C.

The wiring 26C1 is a wiring for electrically connecting the lead 8 and the electrode 4C of the semiconductor chip 4. One end of the wiring 26C1 is located on the plug portion 22 provided on the lead 8 and is electrically connected to the plug portion 22, and the other end of the wiring 26C1 is located on the electrode 4C of the semiconductor chip 4 and is electrically connected to the electrode 4C.

The wiring 26C2 is a wiring for electrically connecting the drain electrode 2D of the semiconductor chip 2 and the electrode 4C of the semiconductor chip 4. One end of the wiring 26C2 is located on the plug portion 22 provided on the die pad 5 and is electrically connected to the plug portion 22, and the other end of the wiring 26C2 is located on the electrode 4C of the semiconductor chip 4 and is electrically connected to the electrode 4C. In this way, the drain electrode 2D of the semiconductor chip 2 and the electrode 4C of the semiconductor chip 4 are electrically connected to each other via the conductive bonding material 10D, the die pad 5, the plug portion 22 (the plug portion 22 formed on the die pad 5), and the wiring 26C2.

The wiring 26C3 is a wiring for electrically connecting the source electrode 3S of the semiconductor chip 3 and the electrode 4C of the semiconductor chip 4. One end of the wiring 26C3 is located on the plug portion 22 provided on the die pad 6 and is electrically connected to the plug portion 22, and the other end of the wiring 26C3 is located on the electrode 4C of the semiconductor chip 4 and is electrically connected to the electrode 4C. In this way, the source electrode 3S of the semiconductor chip 3 and the electrode 4C of the semiconductor chip 4 are electrically connected to each other via the conductive bonding material 10S, the die pad 6, the plug portion 22 (the plug portion 22 formed on the die pad 6), and the wiring 26C3.

The insulating layer 27 is formed on the upper surface of the sealing portion 9 so as to cover the wirings 26. The sealing portion 9 and the insulating layer 27 constitute an insulator portion (sealing insulator portion) 28 configured to seal the semiconductor chips 2, 3, and 4, the die pads 5, 6, and 7, the gate connection conductor portion 6G, and the plurality of leads 8. The die pads 5, 6, and 7, the gate connection conductor portion 6G, and the plurality of leads 8 only need to be at least partially sealed with the insulator portion 28, but it is preferable that the semiconductor chips 2, 3, and 4 are not exposed from the insulator portion 28.

Further, it is also possible to increase the number of wiring layers and insulating layers formed on the sealing portion 9, but in that case, the increased insulating layers also constitute a part of the sealing insulator portion 28.

The wirings (wiring layer, patterned conductor layer) 30 are formed on the insulating layer 27. The wiring 30 is electrically connected to the wiring 26 via an opening (hole) 29 provided in the insulating layer 27.

The wirings 30 include the wiring 30DS electrically connected to the wiring 26DS and the wiring 30C electrically connected to the wiring 26C1. It is preferable to provide a plurality of openings 29 for connecting the wiring 26DS and the wiring 30DS. The wiring 30DS is electrically connected to both the source electrode 2S of the semiconductor chip 2 and the drain electrode 3D of the semiconductor chip 3 via the wiring 26DS. The wiring 30DS corresponds to the terminal T3 in FIG. 1 described above, and can function as an output terminal. The wiring 30C is electrically connected to the lead 8 via the wiring 26C1 and the plug portion 22 (the plug portion 22 formed on the lead 8). For example, a ground potential is supplied to the wiring 30C via the lead 8, the plug portion 22, and the wiring 26C1.

The wirings 26 and 30 and the plug portion 22 constitute the wiring structure of the semiconductor device 1. The gate electrode 2G of the semiconductor chip 2, the gate electrode 3G of the semiconductor chip 3, and the plurality f leads 8 are each electrically connected to the electrode 4C of the semiconductor chip 4 via the wiring structure of the semiconductor device 1. Further, the source electrode 2S of the semiconductor chip 2 and the drain electrode 3D of the semiconductor chip 3 are electrically connected to each other via the wiring structure of the semiconductor device 1.

When mounting the semiconductor device 1 on a substrate, the electronic component 31 (see FIG. 2) can be mounted on the semiconductor device 1. For example, when a coil is mounted as the electronic component 31, one electrode of the electronic component 31 is electrically connected to the wiring 30DS, and the other electrode is electrically connected to the wiring 30C.

Also, when the electronic component 31 is not mounted on the semiconductor device 1, the formation of the wiring 30C can be omitted. Further, the formation of the wiring 30 itself can be omitted, and in that case, a part of the wiring 26DS exposed from the opening of the insulating layer 27 can be used as the output terminal (terminal T3) of the semiconductor device 1.

### Manufacturing Process of Semiconductor Device

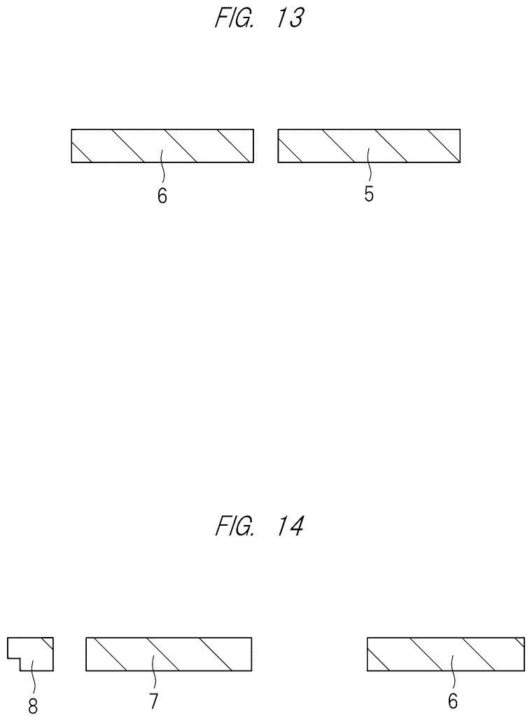

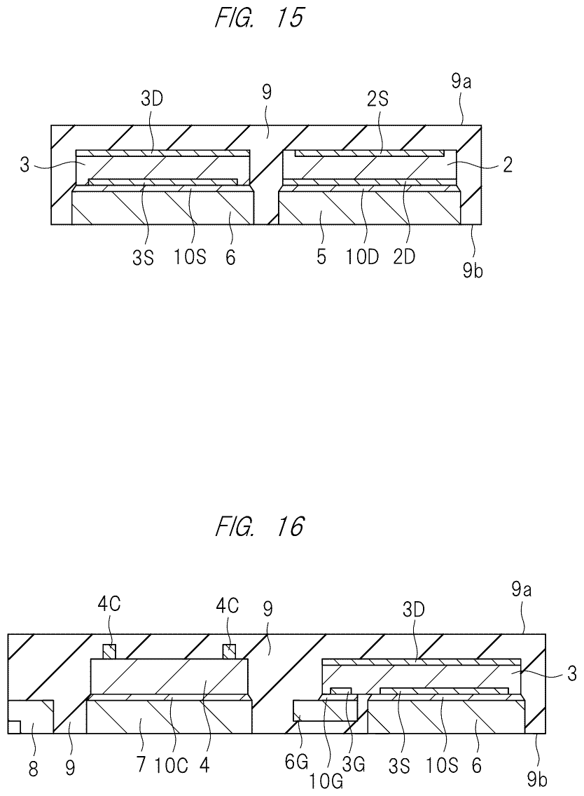

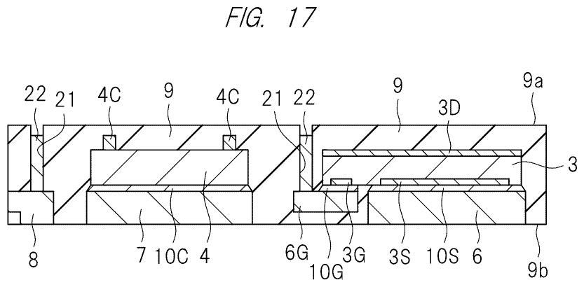

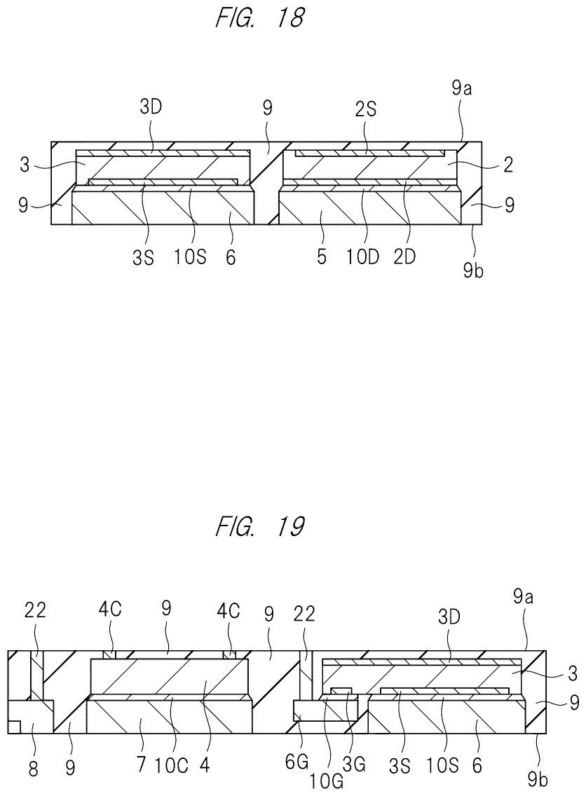

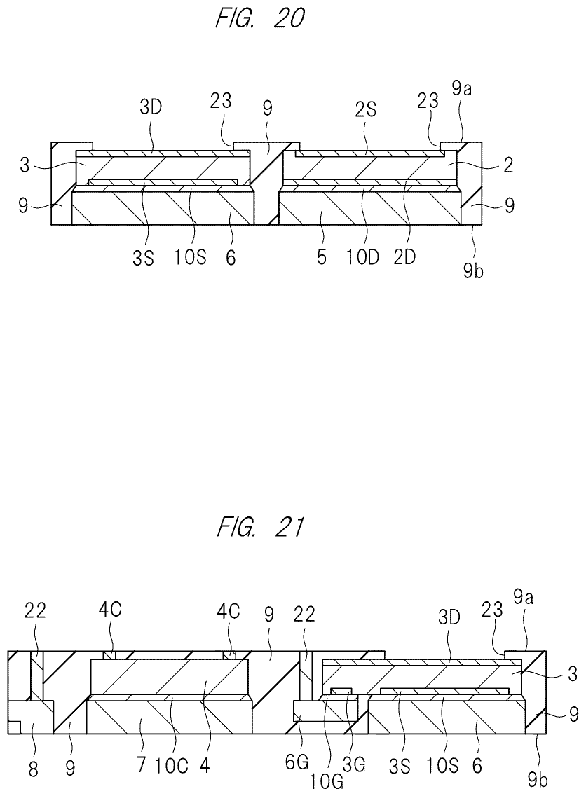

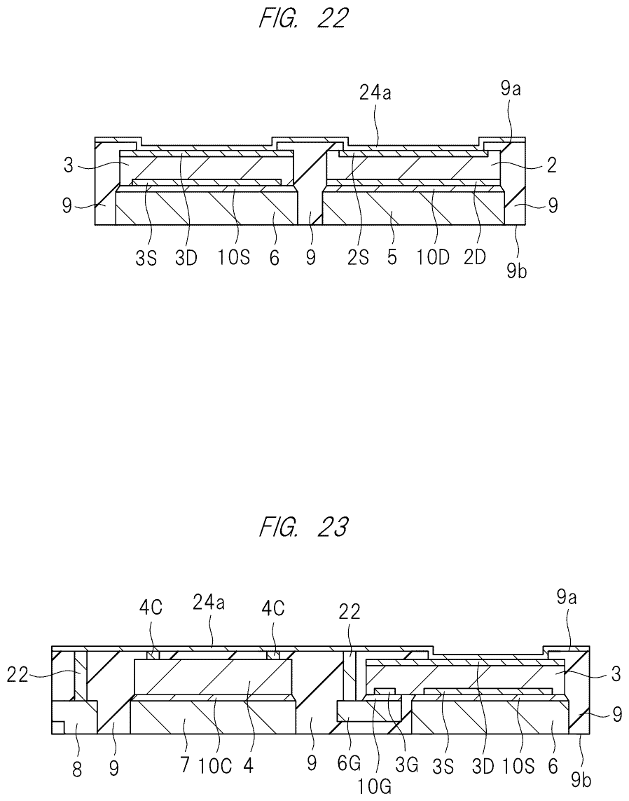

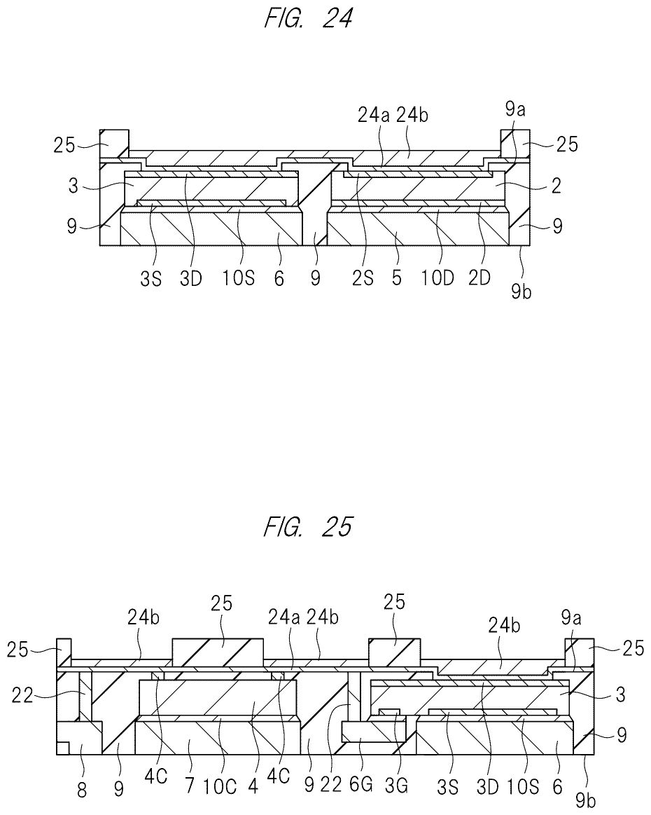

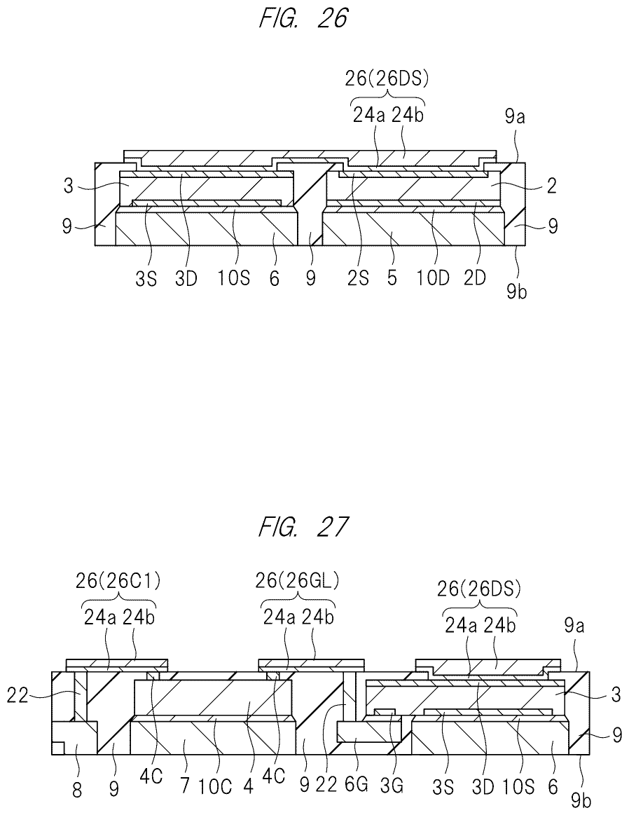

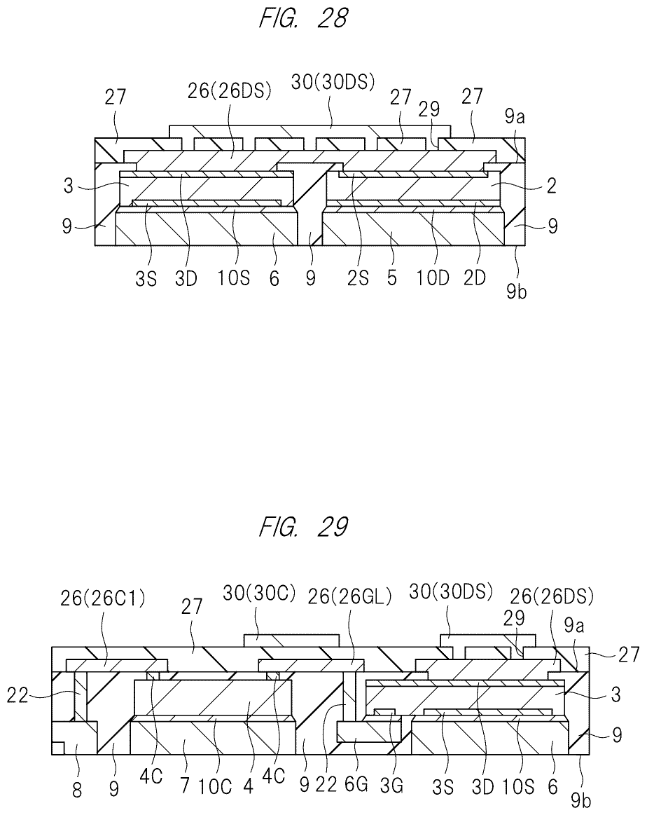

Next, a manufacturing process of the semiconductor device 1 according to the present embodiment will be described. FIG. 13 to FIG. 29 are cross-sectional views each showing a manufacturing step of the semiconductor device 1 according to the present embodiment. In FIG. 13 to FIG. 29, FIG. 13, FIG. 15, FIG. 18, FIG. 20, FIG. 22, FIG. 24, FIG. 26, and FIG. 28 are cross-sectional views of the semiconductor device 1 in each manufacturing step taken along the line A1-A1 in FIG. 4, and FIG. 14, FIG. 16, FIG. 17, FIG. 19, FIG. 21, FIG. 23, FIG. 25, FIG. 27, and FIG. 29 are cross-sectional views of the semiconductor device 1 in each manufacturing step taken along the line A2-A2 in FIG. 4. Although only one package is shown in the drawings, a plurality of packages can be manufactured simultaneously in the state where the plurality of packages are connected in the planar direction. This also applies to other embodiments.

First, as shown in FIG. 13 and FIG. 14, a lead frame is prepared. The lead frame includes a frame (not shown), the die pads 5, 6, and 7 connected to the frame, the gate connection conductor portion 6G, and the plurality of leads 8. The lead frame is used in a state where it is adhered to a back tape (not shown) such as a polyimide film.

Next, as shown in FIG. 15 and FIG. 16, a die bonding process is performed to mount the semiconductor chips 2, 3, and 4 on the die pads 5, 6, and 7. In the die bonding process, the semiconductor chip 2 and the semiconductor chip 3 are upside down (in a vertical direction) with each other when mounted on the die pad. Namely, the semiconductor chip 2 is mounted on the upper surface of the die pad 5 via the conductive bonding material 10D such that the source electrode 2S and the gate electrode 2G face upward and the drain electrode 2D faces the upper surface of the die pad 5. The semiconductor chip 3 is mounted on the upper surface of the die pad 6 via the conductive bonding material 10S and on the upper surface of the gate connection conductor portion 6G via the conductive bonding material 10G such that the drain electrode 3D faces upward, the source electrode 3S faces the upper surface of the die pad 6, and the gate electrode 3G of the semiconductor chip 3 faces the upper surface of the gate connection conductor portion 6G. The semiconductor chip 4 is mounted on the upper surface of the die pad 7 via the insulating or conductive bonding material 10C such that the back surface of the semiconductor chip 4 faces the upper surface of the die pad 7. Thereafter, the bonding materials 10D, 10S, 10G, and 10C are cured. In this way, the semiconductor chip 2 is fixed to the die pad 5, and the drain electrode 2D of the semiconductor chip 2 and the die pad 5 are electrically connected via the conductive bonding material 10D. Also, the semiconductor chip 3 is fixed to the die pad 6, the source electrode 3S of the semiconductor chip 3 and the die pad 6 are electrically connected via the conductive bonding material 10S, and the gate electrode 3G of the semiconductor chip 3 and the gate connection conductor portion 6G are electrically connected via the conductive bonding material 10G. Further, the semiconductor chip 4 is fixed to the die pad 7. As the conductive bonding material, a conductive paste-type bonding material (for example, silver paste), a solder material, or the like can be used. Further, in the case of bonding using a solder material, a stacked structure including a nickel layer can be applied to the electrode on the side of the semiconductor chip to be connected by solder.

Next, as shown in FIG. 15 and FIG. 16, the sealing portion (sealing resin portion) 9 configured to seal the semiconductor chips 2, 3, and 4, the die pads 5, 6, and 7, the gate connection conductor portion 6G, and the plurality of leads 8 is formed. At this stage, the semiconductor chips 2, 3, and 4 and the respective electrodes 2S, 2G, 3D, and 4C thereof are covered with the sealing portion 9 and are not exposed from the sealing portion 9. Further, since the lower surface side of the lead frame is fixed to the back tape, the lower surfaces of the die pads 5, 6, and 7 and the leads 8 are flush with the lower surface 9b of the sealing portion 9. Furthermore, the gate connection conductor portion 6G is made thinner than the lead 8 by half etching from the lower surface side or the like. Therefore, since the sealing portion 9 is also formed on the lower surface of the gate connection conductor portion 6G, the gate connection conductor portion 6G is not exposed on the lower surface 9b of the sealing portion 9.

Next, as shown in FIG. 17, holes 21 are formed in the sealing portion 9 by, for example, laser processing. The holes 21 are formed downward from the upper surface side of the sealing portion 9. The holes 21 are formed on the lead 8, on the gate connection conductor portion 6G, on the die pad 5 at the position that does not overlap the semiconductor chip 2 in plan view, and on the die pad 6 at the position that does not overlap the semiconductor chip 3 in plan view, respectively. At the bottoms of the holes 21, the lead 8, the gate connection conductor portion 6G, the die pad 5, and the die pad 6 are exposed.

Then, conductive plug portions 22 are formed in the holes 21 of the sealing portion 9 by the electrolytic plating or the like. The plug portions 22 are made of a metal material such as copper (Cu), and are formed to fill the holes 21. The plug portion 22 formed on the lead 8 is electrically connected to the lead 8. Also, the plug portion 22 formed on the gate connection conductor portion 6G is electrically connected to the gate connection conductor portion 6G. Further, the plug portion 22 formed on the die pad 5 is electrically connected to the die pad 5. Furthermore, the plug portion 22 formed on the die pad 6 is electrically connected to the die pad 6.

Next, as shown in FIG. 18 and FIG. 19, the upper surface 9a of the sealing portion 9 is polished to reduce the thickness of the sealing portion 9. By polishing the upper surface 9a so as to at least reach the electrode 4C and the plug portion 22, the upper surface of the electrode 4C and the upper surface of the plug portion 22 are exposed from the upper surface 9a of the sealing portion 9.

Next, as shown in FIG. 20 and FIG. 21, openings 23 are formed by the laser processing or the like on the source electrode 2S of the semiconductor chip 2, on the gate electrode 2G, and on the drain electrode 3D of the semiconductor chip 3 in the sealing portion 9. At the bottoms of the openings 23, the source electrode 2S of the semiconductor chip 2, the gate electrode 2G of the semiconductor chip 2, and the drain electrode 3D of the semiconductor chip 3 are exposed. When forming the openings 23 by the laser processing, a copper film of about 4 to 10 μm may be formed in advance on the electrodes 2S, 2G, and 3D in order to prevent the electrodes 2S, 2G, and 3D from being damaged by the laser. At this stage, the back tape is peeled off, thereby exposing the lower surface 9b of the sealing portion 9 and the lower surfaces of the die pads 5, 6, and 7 and the leads 8.

Next, as shown in FIG. 22 and FIG. 23, a metal film 24a is formed by the electroless plating. The metal film 24a is continuously formed on the upper surface 9a of the sealing portion 9, on the source electrode 2S exposed from the opening 23, on the gate electrode 2G, on the drain electrode 3D, on the upper surface of the electrode 4C exposed from the upper surface 9a of the sealing portion 9, and on the upper surface of the plug portion 22 exposed from the upper surface 9a of the sealing portion 9.

Next, as shown in FIG. 24 and FIG. 25, a resist pattern 25 is formed on the metal film 24a. Then, a metal film 24b is formed by the electrolytic plating on the exposed part of the metal film 24a that is not covered with the resist pattern 25. Thereafter, as shown in FIG. 26 and FIG. 27, the resist pattern 25 is removed, and then the exposed part of the metal film 24a that is not covered with the metal film 24b is removed by etching or the like. In this way, the wirings 26 composed of the metal film 24a and the metal film 24b on the metal film 24a are formed. As described above, the wirings 26 include the wiring 26DS, the wiring 26GH, the wiring 26GL, the wiring 26C1, the wiring 26C2, and the wiring 26C3.

Next, as shown in FIG. 28 and FIG. 29, the insulating layer 27 is formed on the upper surface 9a of the sealing portion 9 so as to cover the wirings 26. The insulating layer 27 is made of, for example, an insulating resin material such as a thermosetting resin. Note that the metal film 24a and the metal film 24b constituting the wiring 26 are not shown separately, but are shown integrally for the sake of simplicity in FIG. 28 and FIG. 29 (the same applies to FIG. 8 and FIG. 9 above).

Next, openings 29 are formed in the insulating layer 27. A part of the wiring 26 is exposed at the bottom of the opening 29.

Next, the wirings 30 are formed on the insulating layer 27. Since the method of forming the wiring 30 is basically the same as that of forming the wiring 26, the repetitive description thereof will be omitted here. The wiring 30 is electrically connected to the wiring 26 exposed from the opening 29. As described above, the wirings 30 include the wiring 30DS and the wiring 30C. Thereafter, if an electroless plating film is also formed on the lower surface 9b of the sealing portion 9 when the metal film 24a is formed by the electroless plating, the electroless plating film on the lower surface 9b of the sealing portion 9 is removed by etching or the like.

Thereafter, the semiconductor device 1 can be obtained by cutting between adjacent packages with a dicing blade.

### Main Features and Effects

In a power supply circuit such as a DC-DC converter or an inverter, a field effect transistor for high side switch and a field effect transistor for low side switch are connected in series. If a semiconductor device including a high side semiconductor chip having a field effect transistor for high side switch formed therein and a low side semiconductor chip having a field effect transistor for low side switch formed therein as one package is configured, it is possible to reduce the number of semiconductor devices required to configure a desired circuit as compared with the case where these semiconductor chips are packaged as separate semiconductor devices. However, since the members necessary for the wiring between the electrodes need to be arranged in the semiconductor device in order to electrically connect the source electrode of the high side semiconductor chip and the drain electrode of the low side semiconductor chip in the semiconductor device, there is a concern that the size of the semiconductor device will increase.

The semiconductor device 1 according to the present embodiment includes the die pads 5 and 6, the semiconductor chip 2 mounted on the die pad 5, the semiconductor chip 3 mounted on the die pad 6, and the insulator portion 28 configured to seal them. The semiconductor chip 2 has the source electrode 2S formed on the front surface side and the drain electrode 2D formed on the back surface side, and the semiconductor chip 3 has the source electrode 3S formed on the front surface side and the drain electrode 3D formed on the back surface side.

One of the main features of the present embodiment is that the semiconductor chip 2 and the semiconductor chip 3 are mounted upside down (in a vertical direction) with each other on the die pads. Namely, the semiconductor chip 2 is mounted on the die pad 5 such that the drain electrode 2D faces the die pad 5, and the semiconductor chip 3 is mounted on the die pad 6 such that the source electrode 3S faces the die pad 6. Further, the wiring 26DS that electrically connects the source electrode 2S of the semiconductor chip 2 and the drain electrode 3D of the semiconductor chip 3 is formed in the insulator portion 28.

A case where a high side semiconductor chip (corresponding to the semiconductor chip 2) and a low side semiconductor chip (corresponding to the semiconductor chip 3) are mounted with the same orientation (in a vertical direction) on die pads unlike the present embodiment is assumed, and this will be referred to as a studied example below. In this studied example, both the high side semiconductor chip and the low side semiconductor chip are mounted on the die pads such that the drain electrodes thereof face the die pads. In this case, the high side die pad on which the high side semiconductor chip is mounted is electrically connected to the drain electrode of the high side semiconductor chip, and the low side die pad on which the low side semiconductor chip is mounted is electrically connected to the drain electrode of the low side semiconductor chip.

However, in the case of this studied example, in order to electrically connect the source electrode of the high side semiconductor chip and the drain electrode of the low side semiconductor chip in the semiconductor device, it is conceivable to use a metal plate for electrically connecting the source electrode of the high side semiconductor chip and the low side die pad. However, this requires a region (space) for connecting the low side die pad and the metal plate, resulting in the increase in the size of the semiconductor device. For example, since the source electrode of the high side semiconductor chip and the low side die pad are connected with a metal plate by increasing the gap between the high side semiconductor chip and the low side semiconductor chip, the size of the semiconductor device increases by the amount of increased gap between the semiconductor chips.

Meanwhile, in the present embodiment, the semiconductor chip 2 is mounted on the die pad 5 such that the drain electrode 2D faces the die pad 5, and the semiconductor chip 3 is mounted on the die pad 6 such that the source electrode 3S faces the die pad 6. In this way, both the source electrode 2S of the semiconductor chip 2 and the drain electrode 3D of the semiconductor chip 3 face upward (toward the side opposite to the die pads), and the source electrode 2S of the semiconductor chip 2 and the drain electrode 3D of the semiconductor chip 3 have almost the same height position. Therefore, the source electrode 2S of the semiconductor chip 2 and the drain electrode 3D of the semiconductor chip 3 can be electrically connected easily and accurately by the wiring 26DS formed in the insulator portion 28.

Therefore, in the present embodiment, there is no need to use a metal plate or the like for electrically connecting the die pad 6 on which the semiconductor chip 3 is mounted and the source electrode 2S of the semiconductor chip 2, and it is thus not necessary to secure the space for arranging the metal plate in the semiconductor device and to secure the space for connecting the metal plate to the die pad 6 on which the semiconductor chip 3 is mounted. In the present embodiment, even if the gap between the semiconductor chips 2 and 3 is reduced, the source electrode 2S of the semiconductor chip 2 and the drain electrode 3D of the semiconductor chip 3 can be electrically connected easily and accurately by the wiring 26DS. Therefore, the gap between the semiconductor chips 2 and 3 can be reduced, so that the semiconductor device can be made smaller (reduced in area).

Further, in the present embodiment, the source electrode 2S of the semiconductor chip 2 and the drain electrode 3D of the semiconductor chip 3 are electrically connected by the wiring 26DS having a high degree of freedom in wiring width instead of a metal plate, and the wiring 26DS can connect the source electrode 2S of the semiconductor chip 2 and the drain electrode 3D of the semiconductor chip 3 by the shortest route. Therefore, it becomes easier to realize low impedance and low on-resistance of the semiconductor device, so that the performance of the semiconductor device can be improved.

Also, since it is desirable to increase the wiring width of the wiring 26DS to some extent and connect the source electrode 2S of the semiconductor chip 2 and the drain electrode 3D of the semiconductor chip 3 with low resistance by the wiring 26DS, it is preferable from this viewpoint that the width W1 (see FIG. 5) of the wiring 26DS is larger than the width W2 of the other wirings 26GH, 26GL, 26C1, 26C2, and 26C3. The wiring width mentioned here corresponds to the width (dimension) in a direction substantially perpendicular to the thickness direction of the wiring and substantially perpendicular to the direction of current flowing through the wiring.

In addition, by packaging not only the semiconductor chips 2 and 3 but also the semiconductor chip 4 configured to control them (thus electrically connected to the gate electrodes 2G and 3G of the semiconductor chips 2 and 3) together to form one semiconductor device, it is possible to reduce the number of semiconductor devices required to configure a desired circuit as compared with the case where the semiconductor chip 4 is packaged separately.

Also, it is possible to electrically connect the gate electrode 2G of the semiconductor chip 2 to the electrode 4C of the semiconductor chip 4 by the wiring 26GH formed in the insulator portion 28. Further, it is possible to electrically connect the gate electrode 3G of the semiconductor chip 3 to the electrode 4C of the semiconductor chip 4 by the wiring 26GL formed in the insulator portion 28. Furthermore, it is possible to electrically connect the lead 8 to the electrode 4C of the semiconductor chip 4 by the wiring 26C1 formed in the insulator portion 28. In this way, in the semiconductor device, members to be electrically connected can be electrically connected by the wirings formed in the insulator portion 28. Since the wirings are used instead of metal plates or wires, less space is required for electrical connections, and the semiconductor device can be made smaller (reduced in area). Furthermore, it becomes easier to design the layout of each component of the semiconductor device. Furthermore, the manufacturing cost of the semiconductor device can also be suppressed.

### Second Embodiment

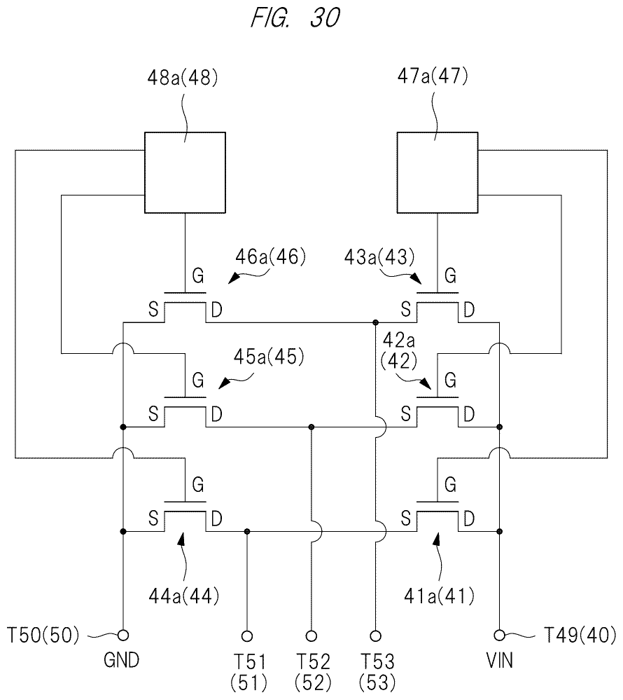

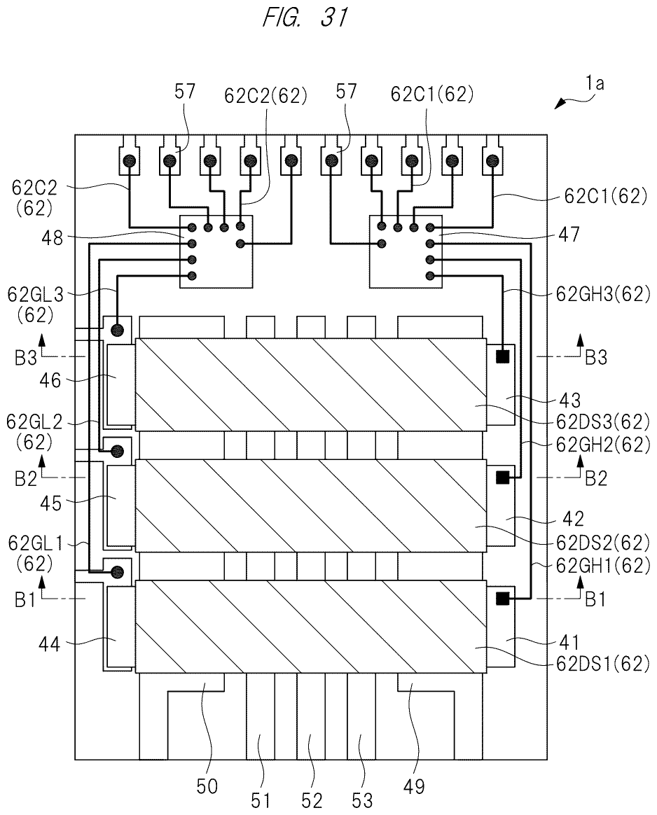

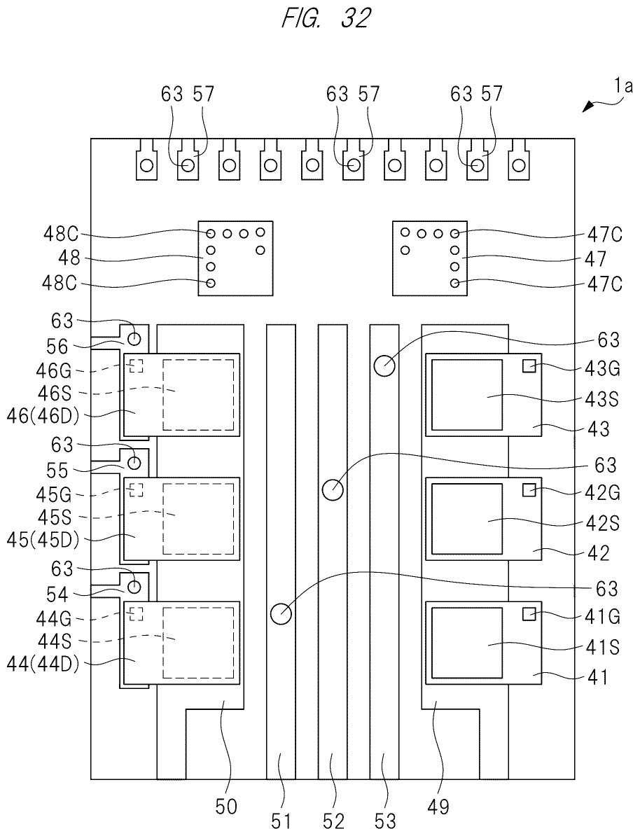

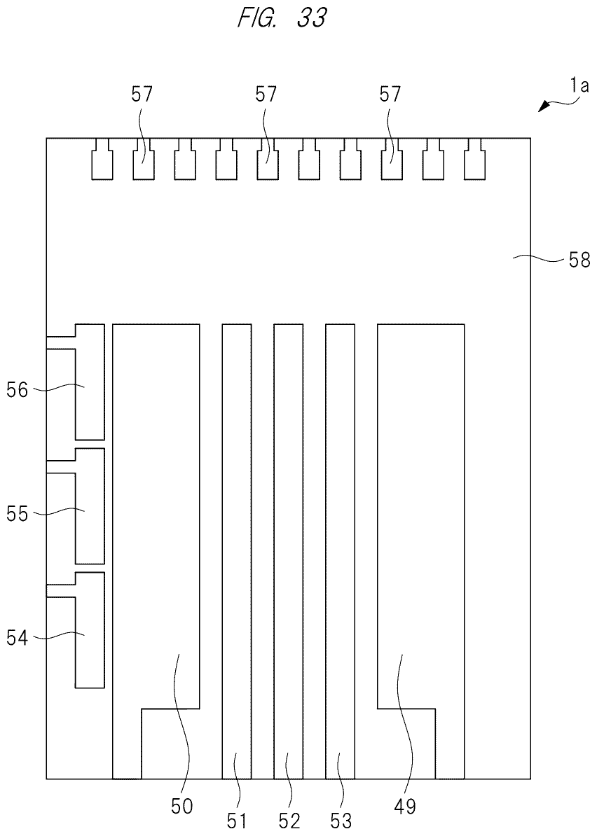

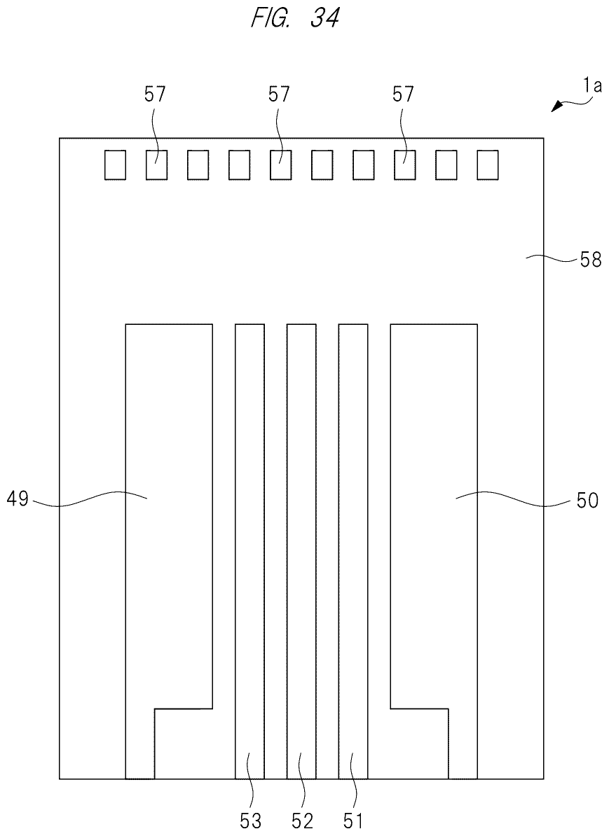

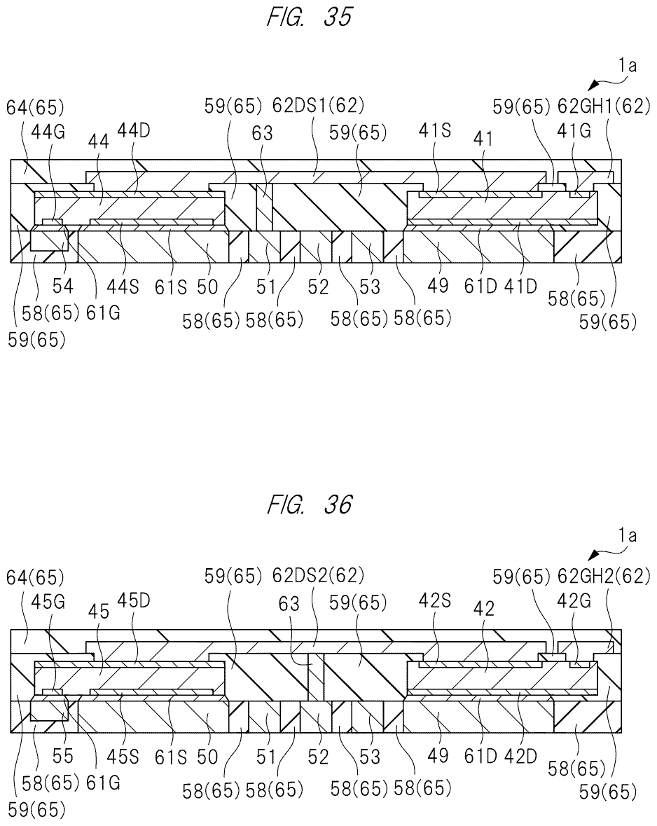

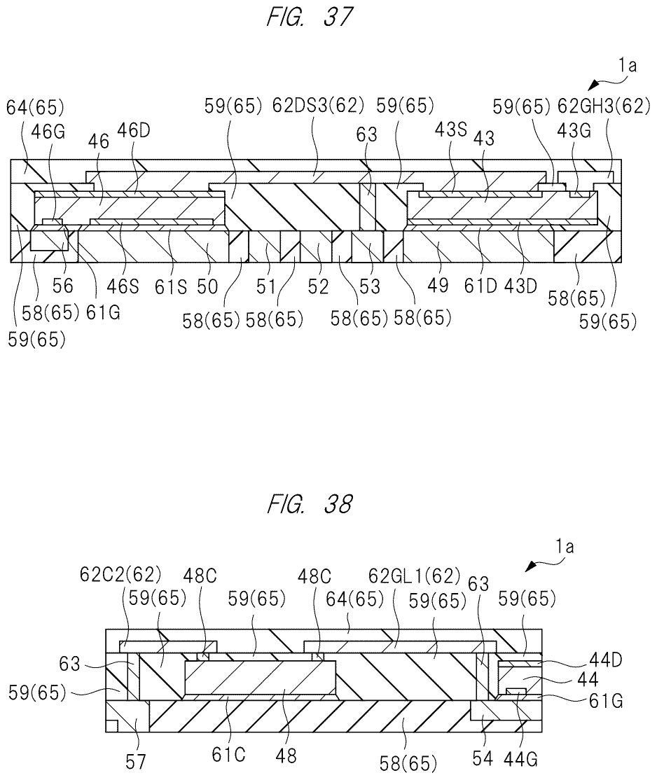

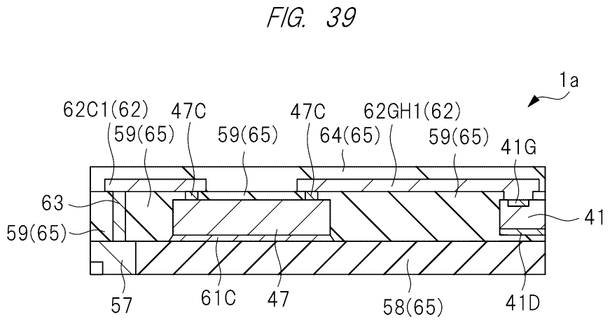

FIG. 30 is a circuit diagram showing a circuit configuration of a semiconductor device 1a according to the second embodiment. FIG. 31 to FIG. 33 are transparent plan views of the semiconductor device 1a according to the second embodiment, FIG. 34 is a bottom view (back view) of the semiconductor device 1a according to the second embodiment, and FIG. 35 to FIG. 39 are cross-sectional views of the semiconductor device 1a according to the second embodiment. Note that FIG. 31 is a transparent plan showing the semiconductor device 1a seen through components made of an insulator (sealing portions 58 and 59 and insulating layer 64). Also, FIG. 32 is a transparent plan view showing the semiconductor device 1a seen further through wirings 62 (wirings 62DS1, 62DS2, 62DS3, 62GH1, 62GH2, 62GH3, 62GL1, 62GL2, 62GL3, 62C1, and 62C2) in FIG. 31. Note that what can be actually seen in FIG. 32 is drain electrodes 44D, 45D, and 46D of semiconductor chips 44, 45, and 46, but the planar positions of gate electrodes 44G, 45G, and 46G and source electrodes 44S, 45S, and 46S in the semiconductor chips 44, 45, and 46 are indicated by dotted lines for ease of understanding. Also, FIG. 33 is a transparent plan view showing the semiconductor device 1a seen further through semiconductor chips 41, 42, 43, 44, 45, 46, 47, and 48 and a plug portion 63 in FIG. 32. In addition, FIG. 35 is a cross-sectional view of the semiconductor device 1a taken at the position of the line B1-B1 shown in FIG. 31, FIG. 36 is a cross-sectional view of the semiconductor device 1a taken at the position of the line B2-B2 shown in FIG. 31, and FIG. 37 is a cross-sectional view of the semiconductor device 1a taken at the position of the line B3-B3 shown in FIG. 31. Further, FIG. 38 is a cross-sectional view of the semiconductor device 1a taken at the position along the wirings 62GL1 and 62C2, and FIG. 39 is a cross-sectional view of the semiconductor device 1a taken at the position along the wirings 62GH1 and 62C1.

Note that the cross-sectional view of the semiconductor device la taken at the position along the wiring 62GL2 and the cross-sectional view of the semiconductor device 1a taken at the position along the wiring 62GL3 are omitted because they have the same structures as that of FIG. 38 although they have different reference numerals. Also, the cross-sectional view of the semiconductor device 1a taken at the position along the wiring 62GH2 and the cross-sectional view of the semiconductor device 1a taken at the position along the wiring 62GH3 are omitted because they have the same structures as that of FIG. 39 although they have different reference numerals.

As shown in the circuit diagram of FIG. 30, a pair of power MOSFETs 41a and 44a, a pair of power MOSFETs 42a and 45a, and a pair of power MOSFETs 43a and 46a each connected in series are connected in parallel between a terminal T49 and a terminal T50. A power supply potential (VIN) is supplied to the terminal T49, and a reference potential lower than the power supply potential, for example, a ground potential (GND) is supplied to the terminal T50. Each gate of the power MOSFETs 41a, 42a, and 43a for high side switches is connected to a control circuit 47a, and each gate of the power MOSFETs 44a, 45a, and 46a for low side switches is connected to a control circuit 48a. A terminal T51 is connected to a source of the power MOSFET 41a and a drain of the power MOSFET 44a, a terminal T52 is connected to a source of the power MOSFET 42a and a drain of the power MOSFET 45a, and a terminal T53 is connected to a source of the power MOSFET 43a and a drain of the power MOSFET 46a. The terminals T51, T52, and T53 are output terminals, and are connected to, for example, a load provided outside the semiconductor device 1a.

In the second embodiment, the semiconductor chips 41, 42, and 43 for high side switches, the semiconductor chips 44, 45, and 46 for low side switches, and the semiconductor chips 47 and 48 for control are collected as one package to constitute the semiconductor device 1a. The structure of the semiconductor device 1a according to the second embodiment will be described below with reference to FIG. 30 to FIG. 39.

The semiconductor device 1a according to the second embodiment includes the semiconductor chips 41, 42, 43, 44, 45, 46, 47, and 48, die pads (chip mounting portions) 49 and 50, and output conductor portions 51, 52, and 53, gate connection conductor portions 54, 55, and 56, a plurality of leads 57, and sealing portions 58 and 59 and an insulating layer 64 configured to seal them.

The power MOSFET 41a is formed in the semiconductor chip 41, and the power MOSFETS 42a to 46a are similarly formed in the semiconductor chips 42 to 46, respectively. The control circuit 47a for controlling the semiconductor chips 41, 42, and 43 for high side switches is formed in the semiconductor chip 47, and the control circuit 48a for controlling the semiconductor chips 44, 45, and 46 for low side switches is formed in the semiconductor chip 48.

The configurations of the semiconductor chips 41, 42, 43, 44, 45, and 46 are the same as those of the semiconductor chips 2 and 3 described above, respectively. Therefore, the semiconductor chip 41 has a source electrode 41S and a gate electrode 41G on the front surface side, and has a drain electrode 41D on the back surface side opposite thereto. Similarly, the semiconductor chips 42 to 46 have source electrodes 42S to 46S and gate electrodes 42G to 46G on the front surface side, and have drain electrodes 42D to 46D on the back surface side opposite thereto, respectively. Also, the semiconductor chip 47 has a plurality of electrodes 47C, which are electrically connected to the control circuit 47a in the semiconductor chip 47, on the front surface side. Further, the semiconductor chip 48 has a plurality of electrodes 48C, which are electrically connected to the control circuit 48a in the semiconductor chip 48, on the front surface side.

The semiconductor chips 41, 42, and 43 are mounted on a common die pad 49 such that the drain electrodes 41D, 42D, and 43D face the die pad 49. The drain electrodes 41D, 42D, and 43D are electrically connected to the common die pad 49 via a conductive bonding material 61D.

The semiconductor chips 44, 45, and 46 are mounted on a common die pad 50 such that the source electrodes 44S, 45S, and 46S face the die pad 50. The source electrodes 44S, 45S, and 46S are electrically connected to the common die pad 50 via a conductive bonding material 61S.

Therefore, in the semiconductor device 1a according to the second embodiment, the semiconductor chips 41, 42, and 43 are mounted with the same orientation (in a vertical direction) and the semiconductor chips 44, 45, and 46 are mounted with the same orientation (in a vertical direction), but the semiconductor chips 41, 42, and 43 and the semiconductor chips 44, 45, and 46 are mounted upside down (in a vertical direction) with each other.

The gate electrode 44G of the semiconductor chip 44 faces the gate connection conductor portion 54, and is electrically connected to the gate connection conductor portion 54 via a conductive bonding material 61G. The gate electrode 45G of the semiconductor chip 45 faces the gate connection conductor portion 55, and is electrically connected to the gate connection conductor portion 55 via the conductive bonding material 61G. The gate electrode 46G of the semiconductor chip 46 faces the gate connection conductor portion 56, and is electrically connected to the gate connection conductor portion 56 via the conductive bonding material 61G.

The die pads 49 and 50, the output conductor portions 51, 52, and 53, the gate connection conductor portions 54, 55, and 56, and the plurality of leads 57 are made of a conductor, are formed of the same material as the die pads 5, 6, and 7 and others, and are separated from each other via the sealing portion 58. The height position of the upper surface of the sealing portion 58 is almost the same as the height positions of the upper surfaces of the die pads 49 and 50, the output conductor portions 51, 52, and 53, the gate connection conductor portions 54, 55, and 56, and the plurality of leads 57. The sealing portion 58 is formed to fill the space between the die pads 49 and 50, the output conductor portions 51, 52, and 53, the gate connection conductor portions 54, 55, and 56, and the plurality of leads 57.

The semiconductor chip 47 and the semiconductor chip 48 are each mounted on the sealing portion 58 via an insulating or conductive bonding material 61C such that the back surfaces of the semiconductor chip 47 and the semiconductor chip 48 face the sealing portion 58. The sealing portion 58 is made of an insulator, and is formed of, for example, the same material as the sealing portion 9 described above. On the lower surface of the sealing portion 58, the lower surfaces of the die pads 49 and 50, the output conductor portions 51, 52, and 53, and the plurality of leads 57 are exposed, but it is preferable that the gate connection conductor portions 54, 55, and 56 are not exposed. This can be realized by, for example, making the gate connection conductor portions 54, 55, and 56 thinner than the die pads 49 and 50 and others 8 by performing half-etching on the lower surface side of the gate connection conductor portions 54, 55, and 56 and covering the lower surfaces of the gate connection conductor portions 54, 55, and 56 with the sealing portion 58.

The sealing portion 59 is formed on the sealing portion 58, the die pads 49 and 50, the output conductor portions 51, 52, and 53, the gate connection conductor portions 54, 55, and 56, and the plurality of leads 57 so as to cover the semiconductor chips 41, 42, 43, 44, 45, 46, 47, and 48. The sealing portion 59 is made of an insulator, and is formed of, for example, the same material as the sealing portion 58.

Openings are formed in the sealing portion 59 so as to expose the source electrodes 41S, 42S, and 43S and the gate electrodes 41G, 42G, and 43G of the semiconductor chips 41, 42, and 43, the drain electrodes 44D, 45D, and 46D of the semiconductor chips 44, 45, and 46, and the electrodes 47C and 48C of the semiconductor chips 47 and 48.

The wirings 62 are formed on the upper surface of the sealing portion 59. The wirings 62 include the wirings 62DS1 to 62DS3, the wirings 62GH1 to 62GH3, the wirings 62GL1 to 62GL3, and the wirings 62C1 and 62C2, and they are formed in the same layer. Also, the conductive plug portion (via portion, via wiring) 63 is formed on each of the output conductor portions 51, 52, and 53, the gate connection conductor portions 54, 55, and 56, and the lead 8. The plug portion 63 is made of a metal material such as copper (Cu), and is formed in a hole provided in the sealing portion 59. The plug portion 63 is provided in order to electrically connect the wiring 62 on the plug portion 63 and each conductor below the plug portion 63 (output conductor portions 51, 52, and 53, gate connection conductor portions 54, 55, and 56, and lead 8).

The wiring 62DS1 is a wiring for electrically connecting the source electrode 41S of the semiconductor chip 41 and the drain electrode 44D of the semiconductor chip 44. The wiring 62DS1 integrally includes a part which is located on the source electrode 41S of the semiconductor chip 41 and is electrically connected to the source electrode 41S, a part which is located on the drain electrode 44D of the semiconductor chip 44 and is electrically connected to the drain electrode 44D, and a part configured to connect them. In this way, the source electrode 41S of the semiconductor chip 41 and the drain electrode 44D of the semiconductor chip 44 are electrically connected via the wiring 62DS1. Further, the plug portion 63 formed on the output conductor portion 51 is interposed between the wiring 62DS1 and the output conductor portion 51. In this way, the wiring 62DS1 and the output conductor portion 51 are electrically connected via the plug portion 63 on the output conductor portion 51.

With the same configuration as the wiring 62DS1, the wiring 62DS2 electrically connects the source electrode 42S of the semiconductor chip 42 and the drain electrode 45D of the semiconductor chip 45, and electrically connects the wiring 62DS2 and the output conductor portion 52 via the plug portion 63 on the output conductor portion 52.

With the same configuration as the wiring 62DS1, the wiring 62DS3 electrically connects the source electrode 43S of the semiconductor chip 43 and the drain electrode 46D of the semiconductor chip 46, and electrically connects the wiring 62DS3 and the output conductor portion 53 via the plug portion 63 on the output conductor portion 53.

The wiring 62GL1 is a wiring for electrically connecting the gate electrode 44G of the semiconductor chip 44 and the electrode 48C of the semiconductor chip 48. One end of the wiring 62GL1 is located on the plug portion 63 provided on the gate connection conductor portion 54 and is electrically connected to the plug portion 63, and the other end of the wiring 62GL1 is located on the electrode 48C of the semiconductor chip 48 and is electrically connected to the electrode 48C. The plug portion 63 arranged between the gate connection conductor portion 54 and the wiring 62GL1 electrically connects the gate connection conductor portion 54 and the wiring 62GL1. In this way, the gate electrode 44G of the semiconductor chip 44 and the electrode 48C of the semiconductor chip 48 are electrically connected via the conductive bonding material 61G, the gate connection conductor portion 54, the plug portion 63, and the wiring 62GL1.

With the same configuration as the wiring 62GL1, the wiring 62GL2 electrically connects the gate electrode 45G of the semiconductor chip 45 and the electrode 48C of the semiconductor chip 48 via the conductive bonding material 61G, the gate connection conductor portion 55, the plug portion 63, and the wiring 62GL2.

With the same configuration as the wiring 62GL1, the wiring 62GL3 electrically connects the gate electrode 46G of the semiconductor chip 46 and the electrode 48C of the semiconductor chip 48 via the conductive bonding material 61G, the gate connection conductor portion 56, the plug portion 63, and the wiring 62GL2.

The wiring 62GH1 is a wiring for electrically connecting the gate electrode 41G of the semiconductor chip 41 and the electrode 47C of the semiconductor chip 47. One end of the wiring 62GH1 is located on the gate electrode 41G of the semiconductor chip 41 and is electrically connected to the gate electrode 41G, and the other end of the wiring 62GH1 is located on the electrode 47C of the semiconductor chip 47 and is electrically connected to the electrode 47C. In this way, the gate electrode 41G of the semiconductor chip 41 and the electrode 47C of the semiconductor chip 47 are electrically connected via the wiring 62GH1.

With the same configuration as the wiring 62GH1, the wiring 62GH2 electrically connects the gate electrode 42G of the semiconductor chip 42 and the electrode 47C of the semiconductor chip 47 via the wiring 62GH2.

With the same configuration as the wiring 62GH1, the wiring 62GH3 electrically connects the gate electrode 43G of the semiconductor chip 43 and the electrode 47C of the semiconductor chip 47 via the wiring 62GH3.

The wiring 62C1 is a wiring for electrically connecting the lead 57 and the electrode 47C of the semiconductor chip 47. One end of the wiring 62C1 is located on the plug portion 63 provided on the lead 57 and is electrically connected to the plug portion 63, and the other end of the wiring 62C1 is located on the electrode 47C of the semiconductor chip 47 and is electrically connected to the electrode 47C. The plug portion 63 arranged between the lead 57 and the wiring 62C1 electrically connects the lead 57 and the wiring 62C1. In this way, the lead 57 and the electrode 47C of the semiconductor chip 47 are electrically connected via the plug portion 63 and the wiring 62C1.

With the same configuration as the wiring 62C1, the wiring 62C2 electrically connects the lead 57 and the electrode 48C of the semiconductor chip 48 via the plug portion 63 and the wiring 62C2.

The insulating layer 64 is formed on the upper surface of the sealing portion 59 so as to cover the wirings 62. The sealing portion 58, the sealing portion 59, and the insulating layer 64 constitute an insulator portion 65 configured to seal the semiconductor chips 41, 42, 43, 44, 45, 46, 47, and 48, the die pads 49 and 50, the output conductor portions 51, 52, and 53, the gate connection conductor portions 54, 55, and 56, and the plurality of leads 57. The die pads 49 and 50, the output conductor portions 51, 52, and 53, the gate connection conductor portions 54, 55, and 56, and the plurality of leads 57 only need to be at least partially sealed with the insulator portion 65, but it is preferable that the semiconductor chips 41, 42, 43, 44, 45, 46, 47, and 48 are not exposed from the insulator portion 65.

Further, it is also possible to increase the number of wiring layers and insulating layers formed on the sealing portion 59, but in that case, the increased insulating layers also constitute a part of the sealing insulator portion 65.

In the semiconductor device 1a, the output conductor portions 51, 52, and 53 correspond to the terminals T51, 152, and T53 in the circuit diagram of FIG. 30, respectively, and function as output terminals. The die pad 49 corresponds to the terminal T49 in the circuit diagram of FIG. 30, and the die pad 50 corresponds to the terminal T50 in the circuit diagram of FIG. 30.

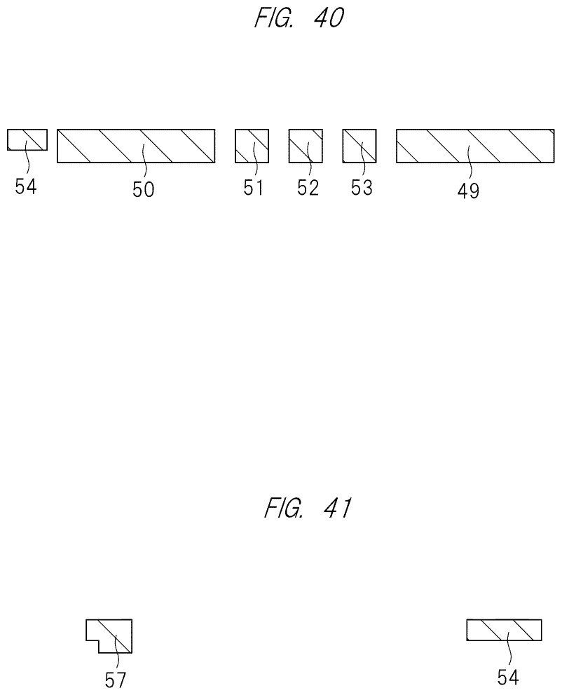

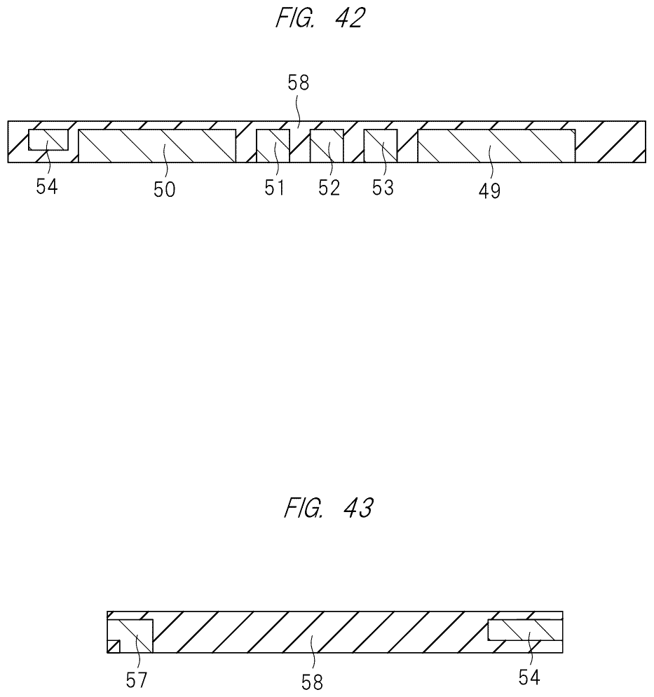

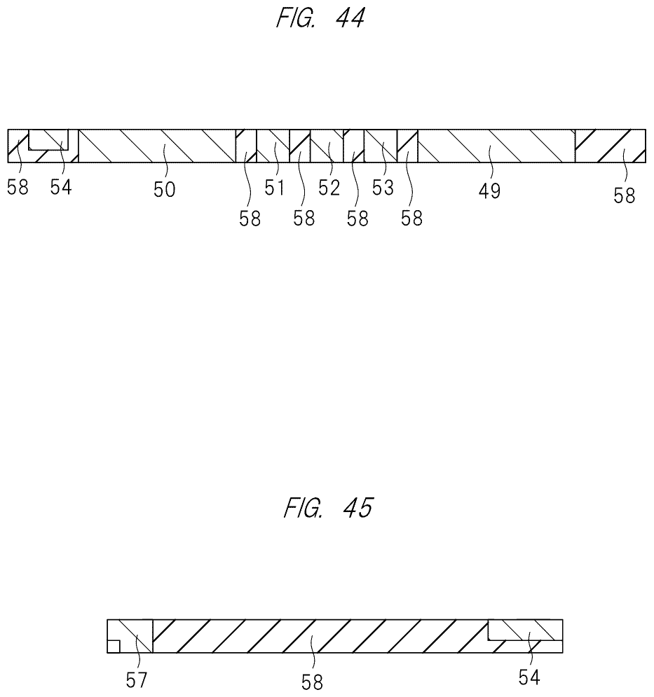

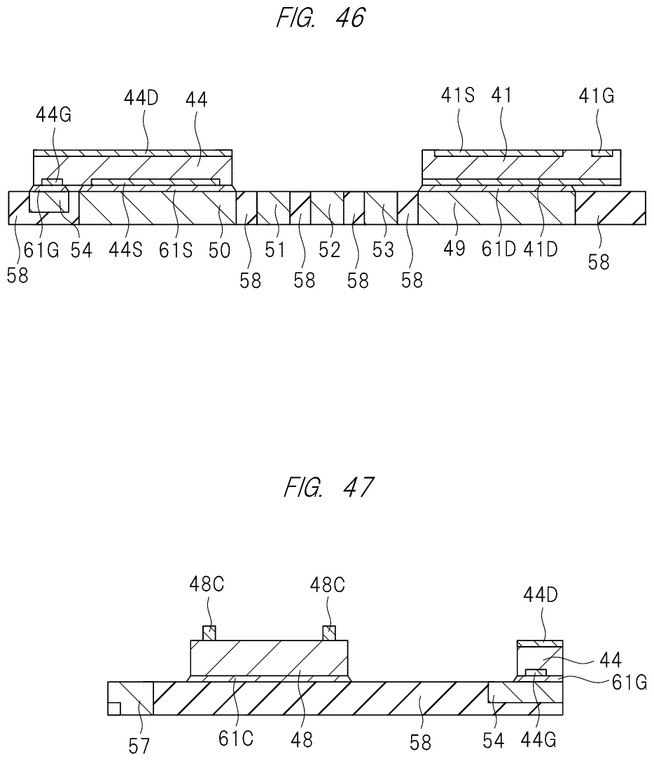

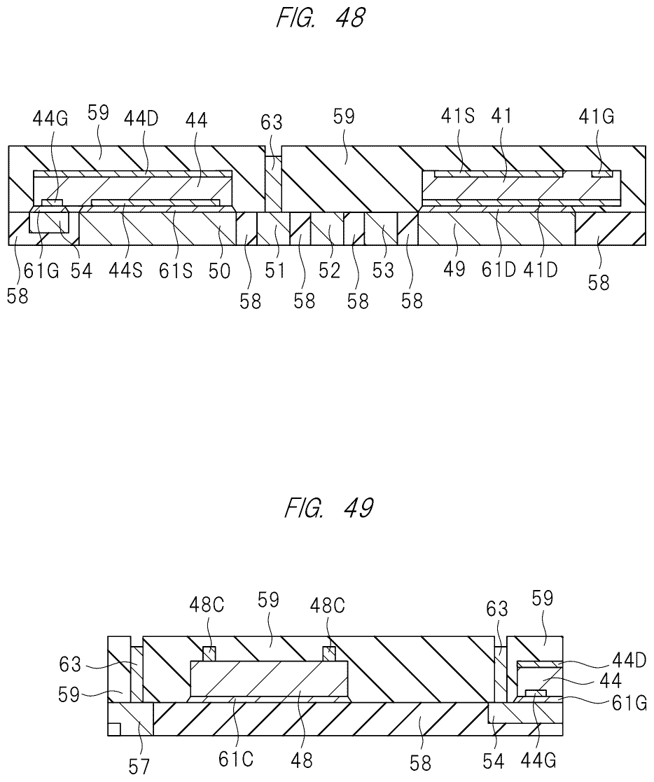

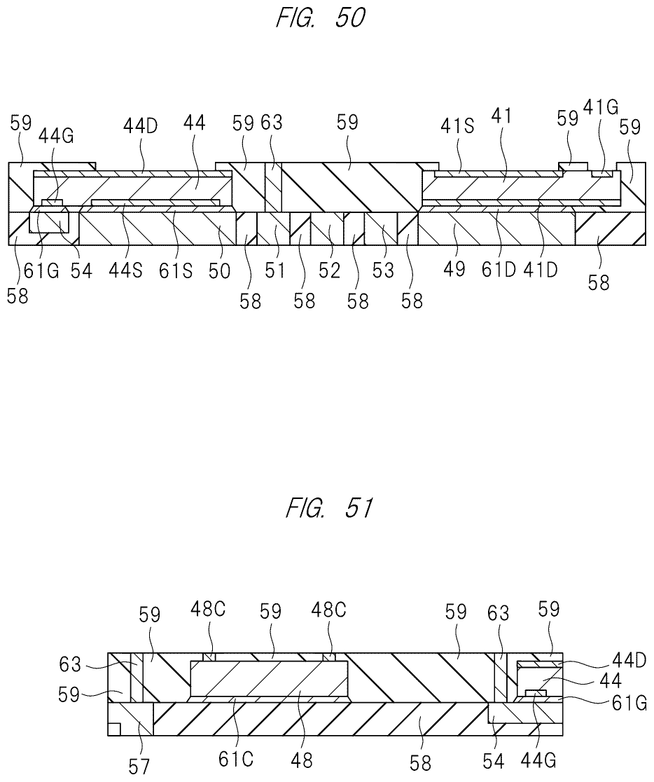

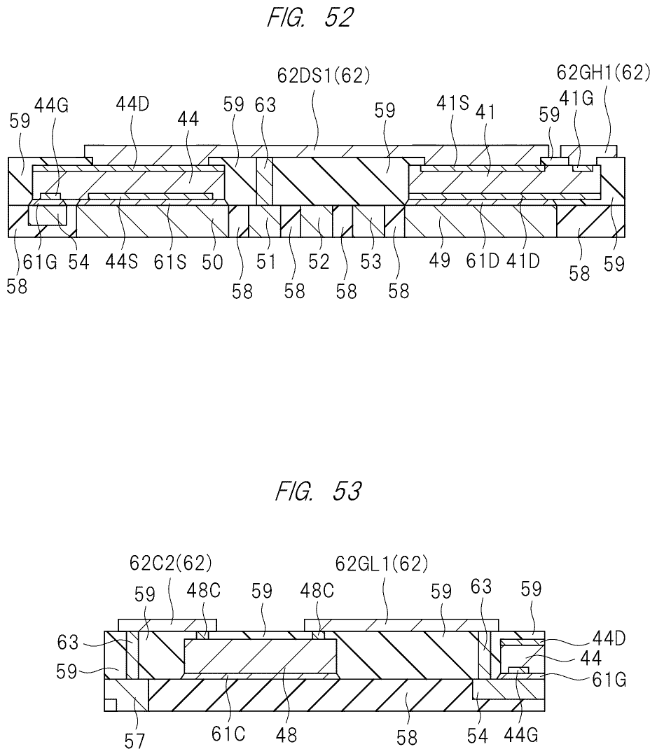

Next, a manufacturing process of the semiconductor device 1a according to the second embodiment will be described with reference to FIG. 31 to FIG. 39 described above and FIG. 40 to FIG. 53. FIG. 40 to FIG. 53 are cross-sectional views each showing a manufacturing step of the semiconductor device 1a according to the second embodiment. In FIG. 40 to FIG. 53, FIG. 40, FIG. 42, FIG. 44, FIG. 46, FIG. 48, FIG. 50, and FIG. 52 are cross-sectional views of the semiconductor device 1a in each manufacturing step taken along the line B1-B1 in FIG. 29. Also, FIG. 41, FIG. 43, FIG. 45, FIG. 47, FIG. 49, FIG. 51, and FIG. 53 are cross-sectional views of the semiconductor device 1a in each manufacturing step taken along the same cross-sectional line as FIG. 36.

First, as shown in FIG. 40 and FIG. 41, a lead frame is prepared. The lead frame includes a frame (not shown here), the die pads 49 and 50 connected to the frame, the output conductor portions 51, 52, and 53, the gate connection conductor portions 54, 55, and 56, and the plurality of leads 57. The lead frame is used in a state where it is adhered to a back tape (not shown) such as a polyimide film.

Next, as shown in FIG. 41 and FIG. 42, the sealing portion 58 is formed. At the stage where the sealing portion 58 is formed, as shown in FIG. 41 and FIG. 42, the thickness of the sealing portion 58 is larger than those of the die pads 49 and 50 and others, and not only the side surfaces of the die pads 49 and 50, the output conductor portions 51, 52, and 53, the gate connection conductor portions 54, 55, and 56, and the plurality of leads 57 but also the upper surfaces thereof are covered with the sealing portion 58. Since the lower surface side of the sealing portion 58 is fixed to the back tape, the lower surfaces of the die pads 49 and 50, the output conductor portions 51, 52, and 53, the gate connection conductor portions 54, 55, and 56, and the plurality of leads 57 are flush with the lower surface of the sealing portion 58.

Next, as shown in FIG. 44 and FIG. 45, the thickness of the sealing portion 58 is reduced by polishing the upper surface of the sealing portion 58. In this way, the upper surfaces of the die pads 49 and 50, the output conductor portions 51, 52, and 53, the gate connection conductor portions 54, 55, and 56, and the plurality of leads 57 are exposed from the sealing portion 58.

Next, as shown in FIG. 46 and FIG. 47, a die bonding process is performed. In the die bonding process, the semiconductor chips 41, 42, and 43 are mounted on the die pad 49, the semiconductor chips 44, 45, and 46 are mounted on the die pad 50, and the semiconductor chips 47 and 48 are mounted on the sealing portion 58.

In the die bonding process, the semiconductor chips 41, 42, and 43 and the semiconductor chips 44, 45, and 46 are mounted upside down (in a vertical direction) with each other when mounted on the die pads. Namely, the semiconductor chips 41, 42, and 43 are mounted on the upper surface of the die pad 49 via the conductive bonding material 61D such that the source electrodes 41S, 42S, and 43S and the gate electrodes 41G, 42G, and 43G face upward and the drain electrodes 41D, 42D, and 43D face the upper surface of the die pad 49. The semiconductor chips 44, 45, and 46 are mounted on the upper surface of the die pad 50 via the conductive bonding material 61S and on the upper surfaces of the gate connection conductor portions 54, 55, and 56 via the conductive bonding material 61G such that the drain electrodes 44D, 45D, and 46D face upward, the source electrodes 44S, 45S, and 46S face the upper surface of the die pad 50, and the gate electrodes 44G, 45G, and 46G face the upper surfaces of the gate connection conductor portions 54, 55, and 56. The semiconductor chips 47 and 48 are mounted on the upper surface of the sealing portion 58 via the insulating or conductive bonding material 61C such that the back surfaces of the semiconductor chips 47 and 48 face the upper surface of the sealing portion 58. As the bonding materials 61D, 61S, and 61G, a conductive paste-type bonding material (for example, silver paste), a solder material, or the like can be used. As the bonding material 61C, for example, DAF (Die Attach Film) can be used.

Next, as shown in FIG. 48 and FIG. 49, the sealing portion 59 configured to seal the semiconductor chips 41, 42, 43, 44, 45, 46, 47, and 48 is formed. At this stage, the semiconductor chips 41 to 48 and the electrodes 41S to 46S, 41G to 46G, 41D to 46D, 47C, and 48C thereof are covered with the sealing portion 59 and are not exposed from the sealing portion 59.

Next, as shown in FIG. 48 and FIG. 49, holes are formed in the sealing portion 59 by, for example, laser processing, and then the conductive plug portions 63 are formed in the holes by electrolytic plating or the like. The plug portions 63 are formed on the leads 57, the output conductor portions 51, 52, and 53, and the gate connection conductor portions 54, 55, and 56, respectively.

Next, as shown in FIG. 50 and FIG. 51, the upper surface of the sealing portion 59 is polished to reduce the thickness of the sealing portion 59. As a result, the upper surfaces of the electrodes 47C and 48C and the upper surface of the plug portion 63 are exposed from the upper surface of the sealing portion 59.

Next, as shown in FIG. 50 and FIG. 51, openings are formed in the sealing portion 59 by laser processing or the like. The openings of the sealing portion 59 are formed on the electrodes 41S to 43S, 41G to 43G, and 44D to 46D of the semiconductor chips 41 to 46 so as to expose these electrodes. At this stage, the back tape is peeled off, whereby the lower surface of the sealing portion 59 and the lower surfaces of the die pads 49 and 50, the output conductor portions 51, 52, and 53, and the leads 57 are exposed.

Next, as shown in FIG. 52 and FIG. 53, the wirings 62 are formed. Since the method of forming the wirings 62 is the same as the method of forming the wirings 26 in the first embodiment described above, the description thereof will be omitted. As described above, the wirings 62 include the wirings 62DS1 to 62DS3, 62GH1 to 62GH3, 62GL1 to 62GL3, 62C1, and 62C2.

Next, as shown in FIG. 35 to FIG. 39 described above, the insulating layer 64 is formed on the upper surface of the sealing portion 59 so as to cover the wirings 62. The insulating layer 64 is made of an insulator, for example, a resin material.

Thereafter, the semiconductor device 1a can be obtained by cutting between adjacent packages with a dicing blade.

In the semiconductor device 1a according to the second embodiment, the semiconductor chips 41, 42, and 43 and the semiconductor chips 44, 45, and 46 are mounted upside down (in a vertical direction) with each other on the die pads. Namely, the semiconductor chips 41, 42, and 43 are mounted on the die pad 49 such that the drain electrodes 41D, 42D, and 43D face the die pad 49, and the semiconductor chips 44, 45, and 46 are mounted on the die pad 50 such that the source electrodes 44S, 45S, and 46S face the die pad 50. Also, the wiring 62DS1 that electrically connects the source electrode 41S of the semiconductor chip 41 and the drain electrode 44D of the semiconductor chip 44, the wiring 62DS2 that electrically connects the source electrode 42S of the semiconductor chip 42 and the drain electrode 45D of the semiconductor chip 45, and the wiring 62DS3 that electrically connects the source electrode 43S of the semiconductor chip 43 and the drain electrode 46D of the semiconductor chip 46 are formed in the insulator portion 65. In this way, the effects described in the first embodiment above can be obtained.

In other words, the source electrodes 41S, 42S, and 43S of the semiconductor chips 41, 42, and 43 and the drain electrodes 44D, 45D, and 46D of the semiconductor chips 44, 45, and 46 face upward (the side opposite to the die pad), and have almost the same height positions. Therefore, the source electrodes 41S, 42S, and 43S of the semiconductor chips 41, 42, and 43 and the drain electrodes 44D, 45D, and 46D of the semiconductor chips 44, 45, and 46 can be electrically connected easily and accurately by the wirings 62DS1, 62DS2, and 62DS3 formed in the insulator portion 65. Since no metal plate is used for connection, there is no need to secure a space necessary for arranging a metal plate in the semiconductor device, and the semiconductor device can be made smaller (reduced in area).

In addition, in the second embodiment, as a configuration in which a plurality of sets of two semiconductor chips that have source electrodes and drain electrodes formed on mutually opposite surfaces and are connected in series are mounted, an example in which three sets of the semiconductor chips are mounted has been shown. However, the number of sets of semiconductor chips may be two or four or more.

### Third Embodiment

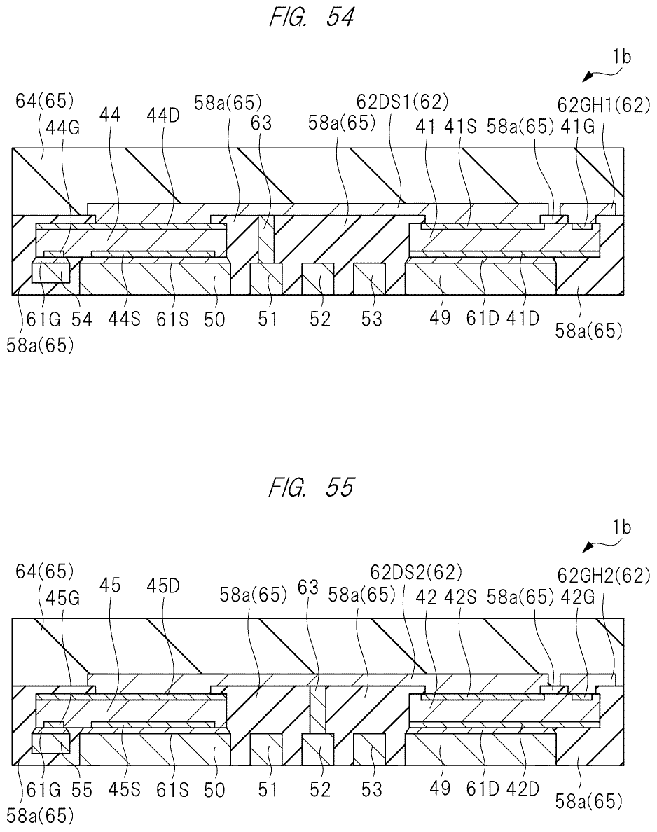

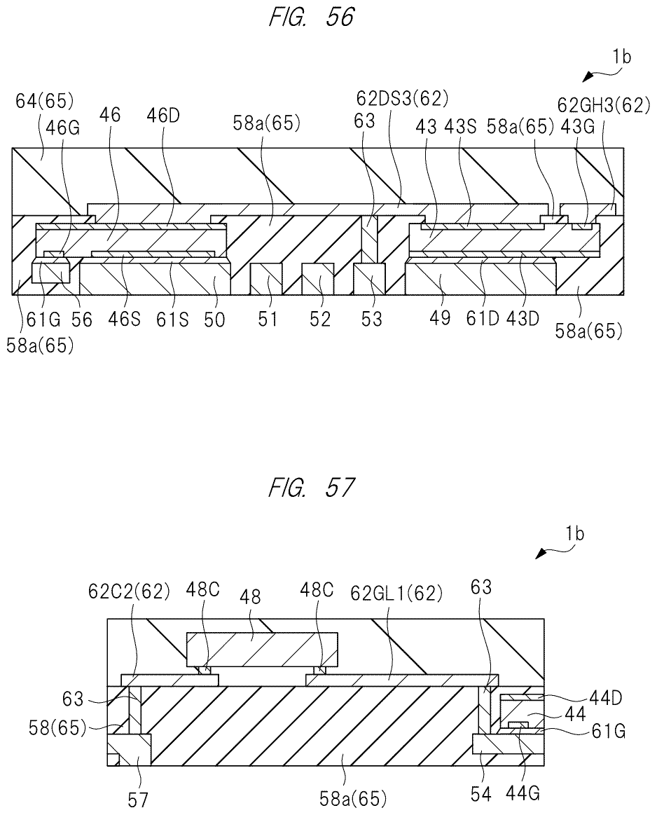

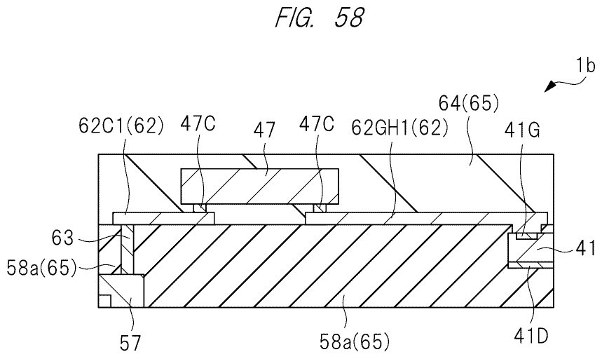

FIG. 54 to FIG. 58 are cross-sectional views of a semiconductor device 1b according to the third embodiment. FIG. 54 corresponds to FIG. 35 described above, FIG. 55 corresponds to FIG. 36 described above, FIG. 56 corresponds to FIG. 37 described above, FIG. 57 corresponds to FIG. 38 described above, and FIG. 58 corresponds to FIG. 39 described above.

FIG. 57 corresponds to a cross-sectional view of the semiconductor device 1b taken at the position along the wiring 62GL1 and the wiring 62C2. The cross-sectional view of the semiconductor device 1b taken at the position along the wiring 62GL2 and the wiring 62C2 and the cross-sectional view of the semiconductor device 1b taken at the position along the wiring 62GL3 and the wiring 62C2 are omitted because they have the same structures as that of FIG. 57 although they have different reference numerals.

FIG. 58 corresponds to a cross-sectional view of the semiconductor device 1b taken at the position along the wiring 62GH1. The cross-sectional view of the semiconductor device 1b taken at the position along the wiring 62GH2 and the cross-sectional view of the semiconductor device 1b taken at the position along the wiring 62GH3 are omitted because they have the same structures as that of FIG. 58 although they have different reference numerals.

The differences between the semiconductor device 1b according to the third embodiment and the semiconductor device 1a according to the second embodiment described above will be described below.

The combination of the sealing portion 58 and the sealing portion 59 in the semiconductor device 1a according to the second embodiment described above corresponds to a sealing portion 58a in the semiconductor device 1b according to the third embodiment. In the third embodiment, the semiconductor chips 47 and 48 are mounted on an upper surface of the sealing portion 58a. Further, in the third embodiment, the insulating layer 64 is formed on the upper surface of the sealing portion 58a so as to cover the wirings 62 and the semiconductor chips 47 and 48. Since the semiconductor chips 47 and 48 are mounted on the sealing portion 58a, the thickness of the insulating layer 64 in the third embodiment is larger than the thickness of the insulating layer 64 in the second embodiment described above. The insulator portion 65 in the third embodiment is composed of the sealing portion 58a and the insulating layer 64.

Also, in the case of the third embodiment, each of the plurality of electrodes 47C of the semiconductor chip 47 is located on any of the wirings 62GH1, 62GH2, 62GH3, and 62C1 and is electrically connected thereto. Further, each of the plurality of electrodes 48C of the semiconductor chip 48 is located on any of the wirings 62GL1, 62GL2, 62GL3, and 62C2 and is electrically connected thereto. In this way, in the third embodiment as well, the gate electrodes 41G, 42G, and 43G of the semiconductor chips 41, 42, and 43 can be electrically connected to the electrodes 47C of the semiconductor chip 47 via the wirings 62GH1, 62GH2, and 62GH3 as in the second embodiment, and the lead 57 can be electrically connected to the electrode 47C of the semiconductor chip 47 via the wiring 62C1. Also, the gate electrodes 44G, 45G, and 46G of the semiconductor chips 44, 45, and 46 can be electrically connected to the electrodes 48C of the semiconductor chip 48 via the wirings 62GL1, 62GL2, and 62GL3, and the lead 57 can be electrically connected to the electrode 48C of the semiconductor chip 48 via the wiring 62C2.

Since the other configuration of the semiconductor device 1b according to the third embodiment is the same as that of the semiconductor device 1a according to the second embodiment described above, the repetitive description thereof will be omitted.

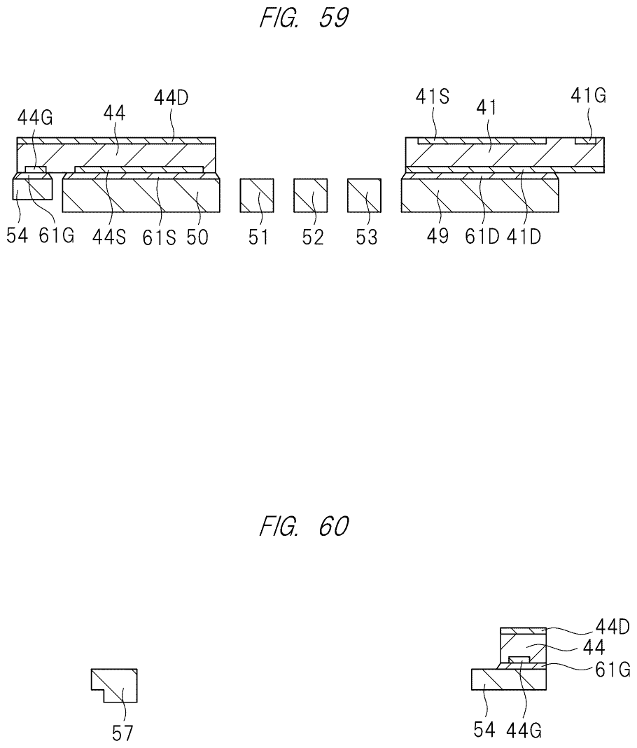

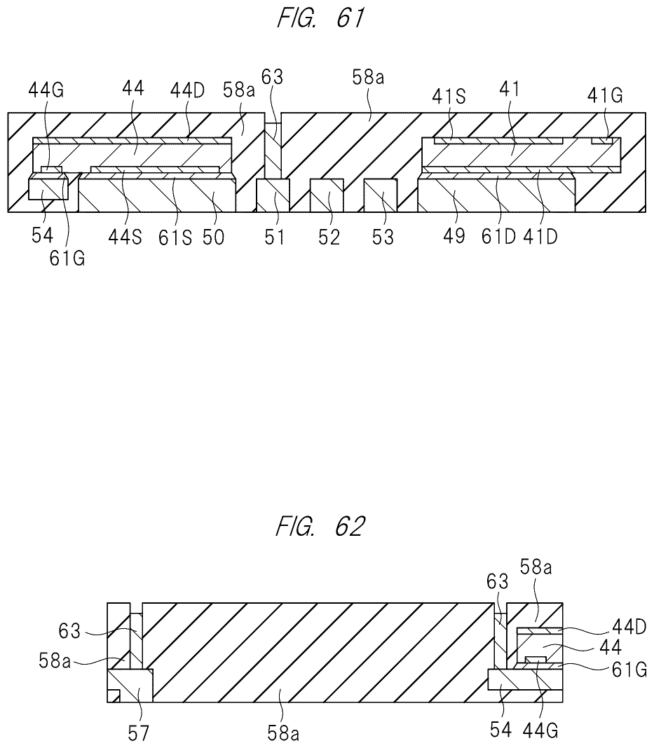

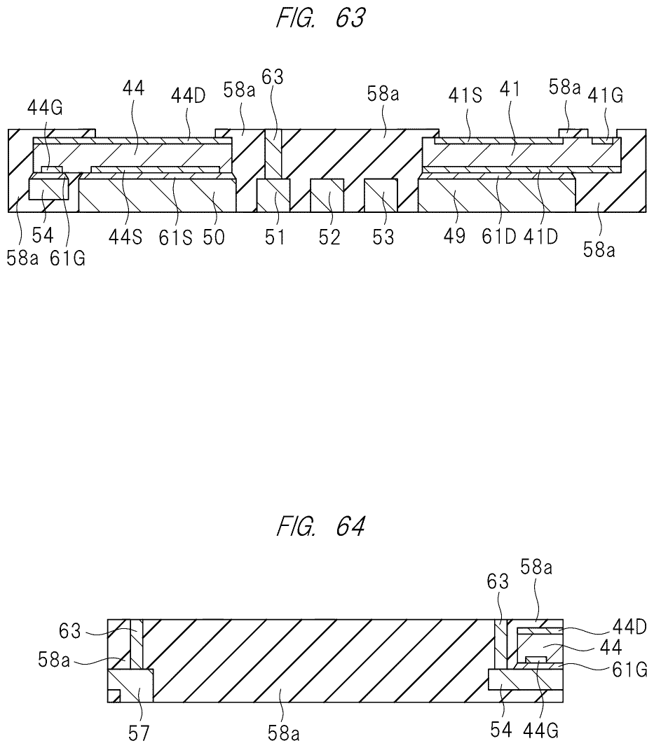

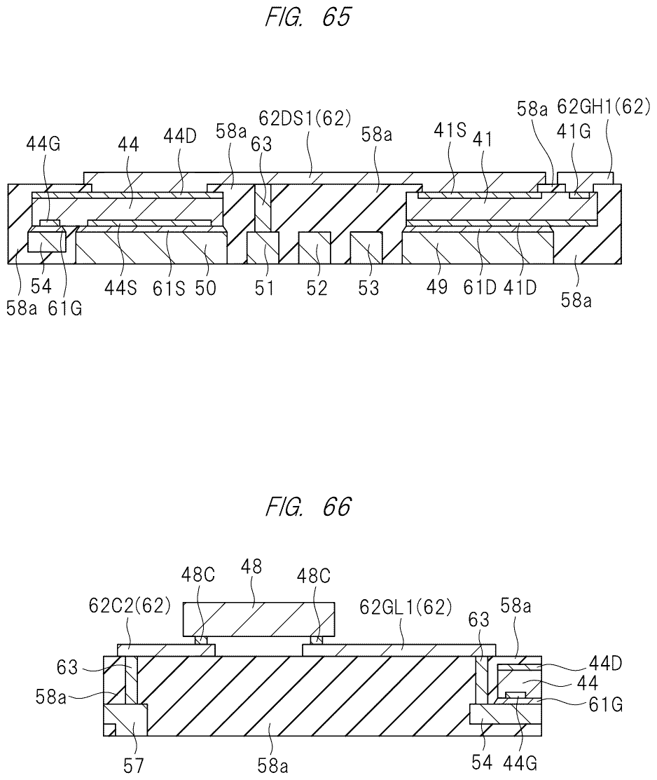

Next, a manufacturing process of the semiconductor device 1b according to the third embodiment will be described. FIG. 59 to FIG. 66 are cross-sectional views each showing a manufacturing step of the semiconductor device 1b according to the third embodiment. In FIG. 59 to FIG. 66, FIG. 59, FIG. 61, FIG. 63, and FIG. 65 are cross-sectional views in each manufacturing step taken along the same cross-sectional line as FIG. 50, and FIG. 60, FIG. 62, FIG. 64, and FIG. 66 are cross-sectional views in each manufacturing step taken along the same cross-sectional line as FIG. 53.

First, as shown in FIG. 59 and FIG. 60, a lead frame similar to that in the second embodiment described above is prepared. The lead frame includes a frame, the die pads 49 and 50 connected to the frame, the output conductor portions 51, 52, and 53, the gate connection conductor portions 54, 55, and 56, and the plurality of leads 57. The lead frame is used in a state where it is adhered to a back tape (not shown) such as a polyimide film.

Next, as shown in FIG. 59 and FIG. 60, a die bonding process is performed to mount the semiconductor chips 41, 42, and 43 on the die pad 49 and mount the semiconductor chips 44, 45, and 46 on the die pad 50. Since the die bonding of the semiconductor chips 41, 42, and 43 and the semiconductor chips 44, 45, and 46 in the third embodiment is the same as that in the second embodiment, the repetitive description thereof will be omitted here. However, in the case of the third embodiment, the die bonding of the semiconductor chips 47 and 48 is not performed at this stage.

Next, as shown in FIG. 61 and FIG. 62, the sealing portion 58a configured to seal the semiconductor chips 41, 42, 43, 44, 45, and 46, the die pads 49 and 50, the output conductor portions 51, 52, and 53, the gate connection conductor portion 54, 55, and 56, and the plurality of o leads 57 is formed. At this stage, the semiconductor chips 41, 42, 43, 44, 45, and 46 and the electrodes thereof are covered with the sealing portion 58a and are not exposed from the sealing portion 58a. Since the lower surface side of the sealing portion 58a is covered with the back tape, the lower surfaces of the die pads 49 and 50, the output conductor portions 51, 52, and 53, and the plurality of leads 57 are flush with the lower surface of the sealing portion 58a.

Next, as shown in FIG. 61 and FIG. 62, holes are formed in the sealing portion 58a by, for example, laser processing so as to reach the output conductor portions 51, 52, and 53, the gate connection conductor portions 54, 55, and 56, and the plurality of leads 57, and then the conductive plug portions 63 are formed in the holes by electrolytic plating or the like.

Next, as shown in FIG. 63 and FIG. 64, the upper surface of the sealing portion 58a is polished to reduce the thickness of the sealing portion 59. When the polishing process of the sealing portion 58a is completed, upper surfaces of the plug portions 63 are exposed from the upper surface of the sealing portion 58a.

Next, as shown in FIG. 63 and FIG. 64, openings are formed in the sealing portion 58a by laser processing or the like. The openings of the sealing portion 58a are formed on the electrodes 41S to 43S, 41G to 43G, and 44D to 46D of the semiconductor chips 41 to 46 so as to expose these electrodes from the sealing portion 58a. At this stage, the back tape is peeled off, whereby the lower surface of the sealing portion 58a and the lower surfaces of the die pads 49 and 50, the output conductor portions 51, 52, and 53, and the leads 57 are exposed.

Next, as shown in FIG. 65 and FIG. 66, the wirings 62 are formed. Since the method of forming the wirings 62 is basically the same as the method of forming the wirings 26 in the first embodiment described above and the method of forming the wirings 62 in the second embodiment described above, the description thereof will be omitted here. In the present embodiment as well, the wirings 62 include the wirings 62DS1, 62DS2, 62DS3, 62GH1, 62GH2, 62GH3, 62GL1, 63GL2, 62GL3, 62C1, and 62C2 as in the second embodiment described above.

Next, as shown in FIG. 65 and FIG. 66, a die bonding process is performed to mount the semiconductor chips 47 (not shown) and 48 on the sealing portion 58a. The semiconductor chips 47 and 48 are mounted on the sealing portion 58a such that the electrodes 47C and 48C of the semiconductor chips 47 and 48 face the sealing portion 58a. The plurality of electrodes 47C of the semiconductor chip 47 and the wirings 62GH1, 62GH2, 62GH3, and 62C1 are electrically connected to each other, and the plurality of electrodes 48C of the semiconductor chip 48 and the wirings 62GL1, 62GL2, 62GL3, and 62C2 are electrically connected to each other.

Next, as shown in FIG. 54 to FIG. 58 described above, the insulating layer 64 is formed on the upper surface of the sealing portion 58a so as to cover the wirings 62 and the semiconductor chips 47 and 48.

Thereafter, the semiconductor device 1b can be obtained by cutting between adjacent packages with a dicing blade.

In the third embodiment, the semiconductor chips 47 and 48 for control are both flip-chip connected face down. Therefore, if flip-chip connection of the semiconductor chips 47 and 48 is desired, it is preferable to apply the third embodiment. On the other hand, since the semiconductor chips 47 and 48 for control are both connected face up and the semiconductor chips 47 and 48 are not mounted on the sealing portion 59 in the second embodiment described above, the thickness of the insulating layer 64 can be made relatively small. Therefore, the thickness of the entire semiconductor device can be reduced.

### Fourth Embodiment

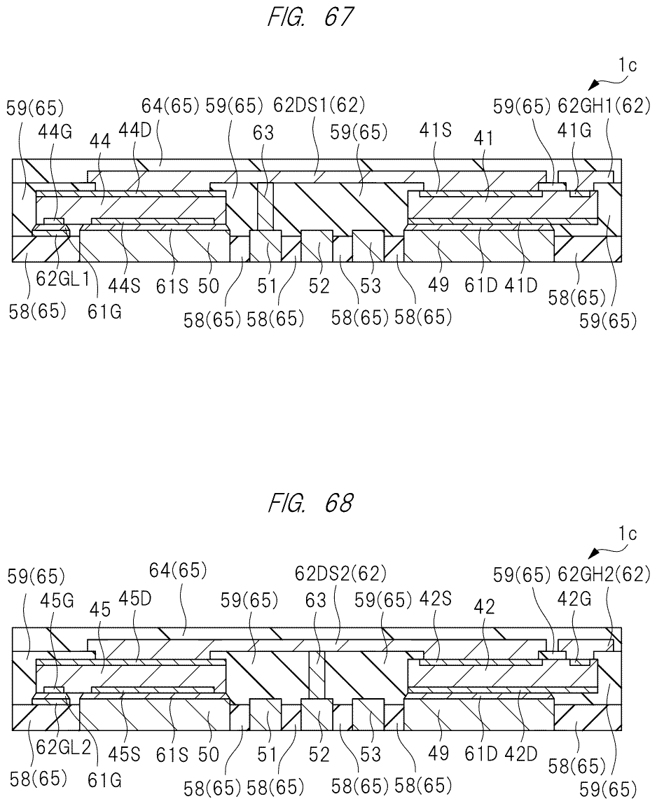

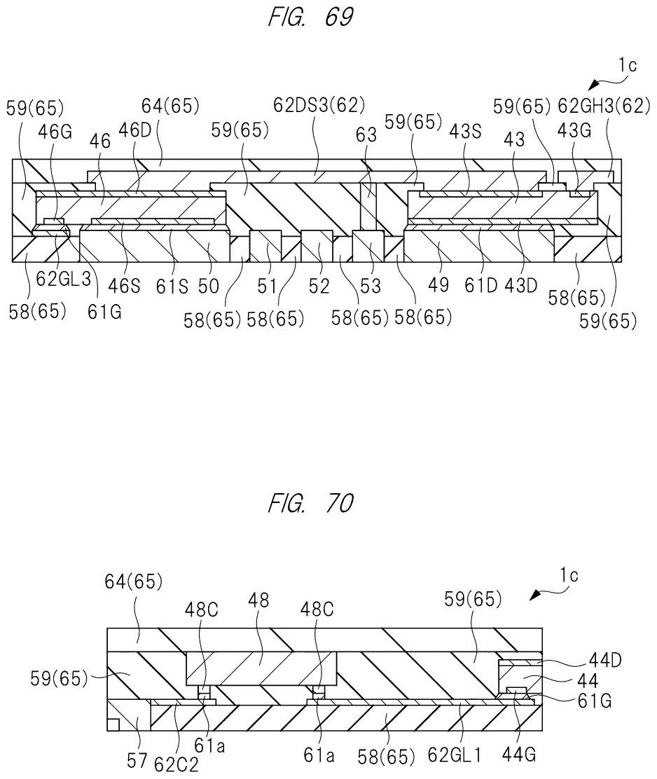

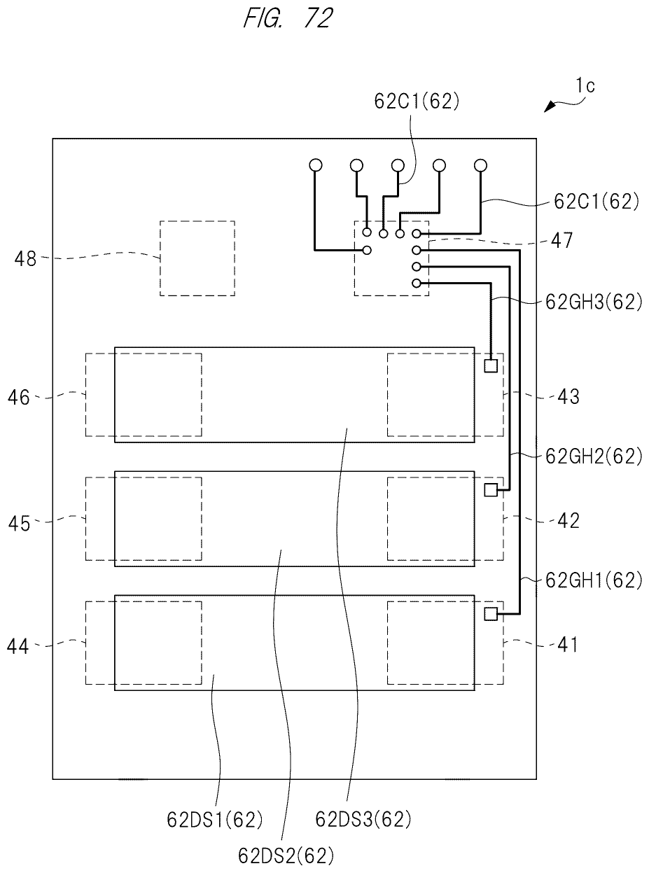

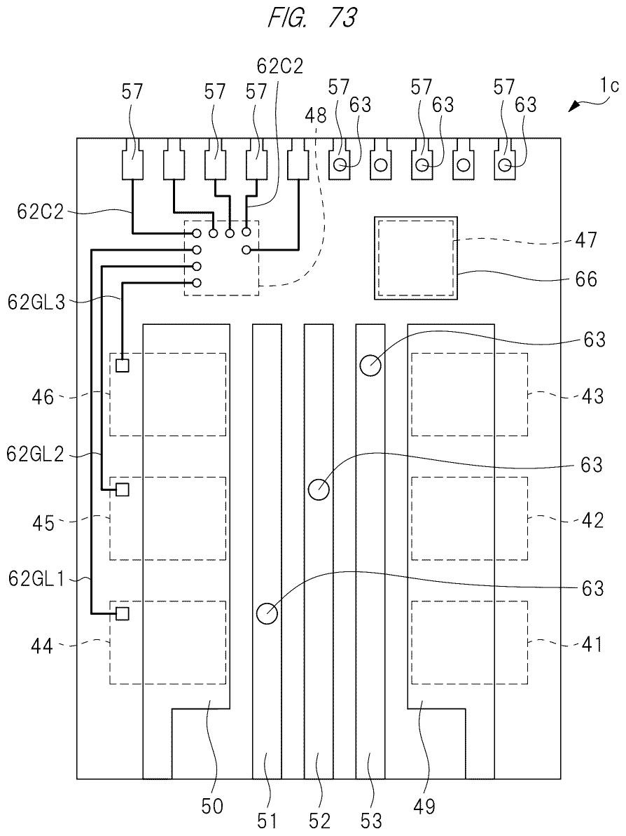

FIG. 67 to FIG. 71 are cross-sectional views of a semiconductor device 1c according to the fourth embodiment. FIG. 72 and FIG. 73 are transparent plan views of the semiconductor device 1c according to the fourth embodiment. FIG. 72 shows the wirings 62, and the positions of the semiconductor chips 41, 42, 43, 44, 45, 46, 47, and 48 are indicated by dotted lines. Also, FIG. 73 shows the die pads 49 and 50, the output conductor portions 51, 52, and 53, the leads 57, the wirings 62GL1, 62GL2, 62GL3, and 62C2, the plug portions 63, and a conductor pattern 66, and the positions of the semiconductor chips 41, 42, 43, 44, 45, 46, 47, and 48 are indicated by dotted lines.

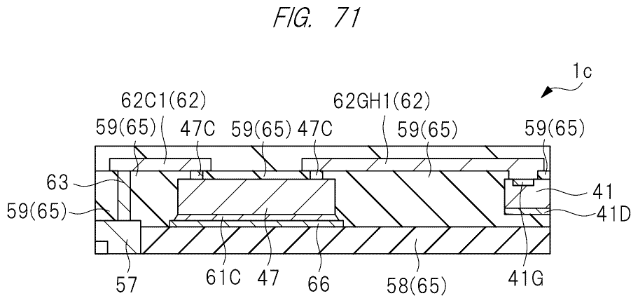

Note that FIG. 70 corresponds to a cross-sectional view of the semiconductor device 1c taken at the position along the wiring 62GL1 and the wiring 62C2. The cross-sectional view of the semiconductor device 1c taken at the position along the wiring 62GL2 and the wiring 62C2 is omitted because it has the similar structure to that of FIG. 70 although they have different reference numerals. Similarly, the cross-sectional view of the semiconductor device 1c taken at the position along the wiring 62GL3 and the wiring 62C2 is also omitted. Further, FIG. 71 corresponds to a cross-sectional view of the semiconductor device 1c taken at the position along the wiring 62GH1 and the wiring 62C1. The cross-sectional view of the semiconductor device 1c taken at the position along the wiring 62GH2 and the wiring 62C1 is omitted because it has the similar structure to that of FIG. 71 although they have different reference numerals. Similarly, the cross-sectional view of the semiconductor device 1c taken at the position along the wiring 62GH3 and the wiring 62C1 is also omitted.

The differences between the semiconductor device 1c according to the fourth embodiment and the semiconductor device 1a according to the second embodiment described above will be described below.

In the case of the second embodiment described above, the semiconductor chips 47 and 48 for control are both mounted on the sealing portion 58. Meanwhile, in the fourth embodiment, the semiconductor chip 47 of the semiconductor chips 47 and 48 for control is mounted on the sealing portion 58, and the other semiconductor chip 48 is mounted on the conductor pattern 66. As a result, the wirings 62GL1, 62GL2, and 62GL3 for electrically connecting the gate electrodes 44G, 45G, and 46G of the semiconductor chips 44, 45, and 46 to the electrodes 48C of the semiconductor chip 48 and the wiring 62C2 for electrically connecting the electrode 48C of the semiconductor chip 48 to the lead 57 are formed on the sealing portion 58 (that is, between the sealing portion 58 and the sealing portion 59) instead of on the sealing portion 59.

In the fourth embodiment, the wirings 62GL1, 62GL2, 62GL3, and 62C2 and the chip mounting conductor pattern 66 are formed on the upper surface of the sealing portion 58. Then, the semiconductor chip 47 is mounted and fixed on the conductor pattern 66 via the bonding material 61C such as solder such that the electrodes 47C of the semiconductor chip 47 faces upward and the back surface of the semiconductor chip 47 faces the conductor pattern 66 (sealing portion 58). The semiconductor chip 48 is mounted on the sealing portion 58 such that the electrodes 48 of the semiconductor chip 48 face the sealing portion 58, and each of the plurality of electrodes 48C is located on any of the wirings 62GL1, 62GL2, 62GL3, and 62C2 and is electrically connected thereto via a conductive bonding material 61a.

In the case of the fourth embodiment, no gate connection conductor portion is formed. The gate electrodes 44G to 46G of the semiconductor chips 44 to 46 are electrically connected to the electrodes 48C of the semiconductor chip 48 via the wirings 62GL1 to 62GL3 without the plug portion. The lead 57 and the electrode 48C of the semiconductor chip 48 are electrically connected via the wiring 62C2 without the plug portion.

Since the other configuration of the semiconductor device 1c according to the fourth embodiment is substantially the same as that of the semiconductor device 1a according to the second embodiment described above, the repetitive description thereof will be omitted here.

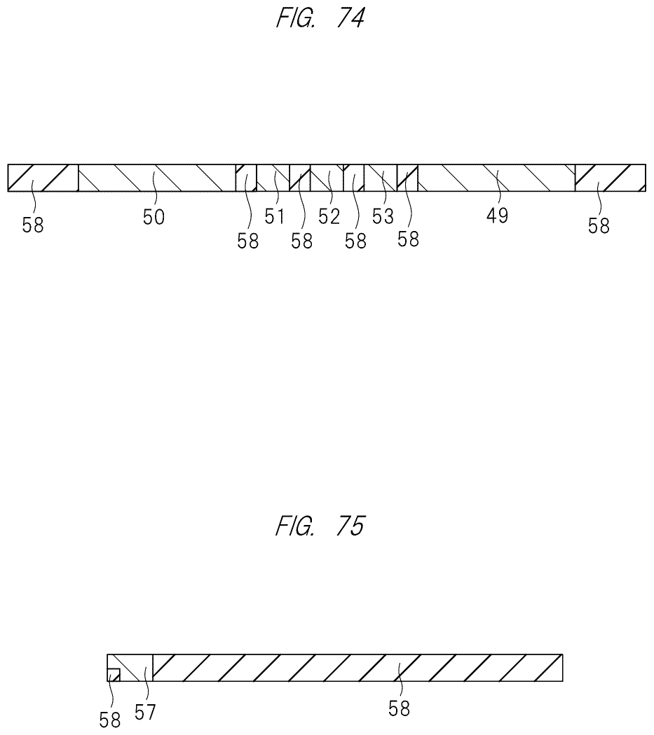

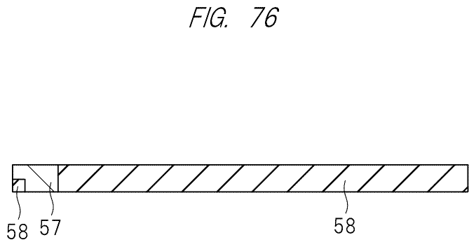

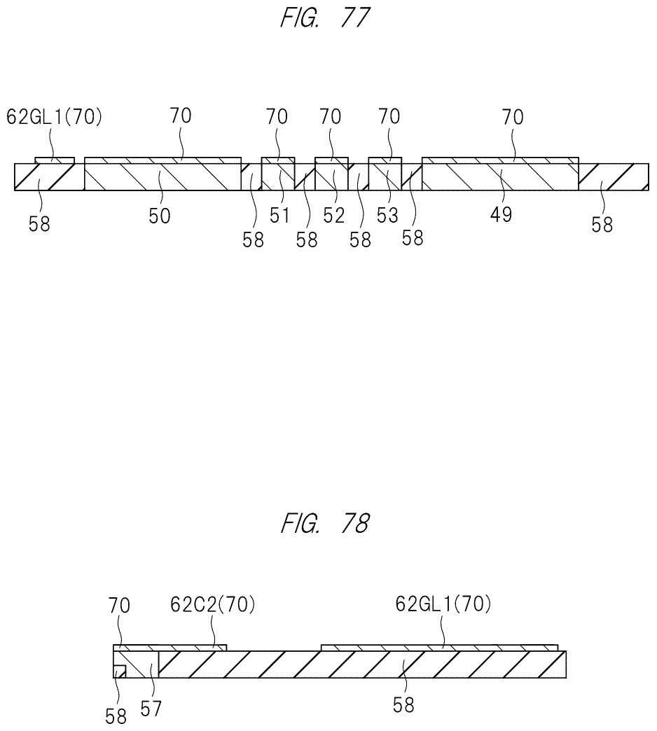

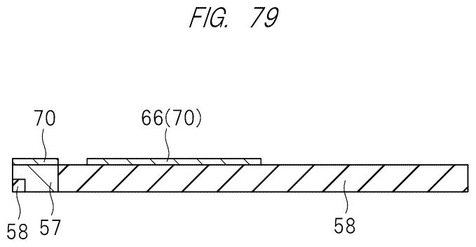

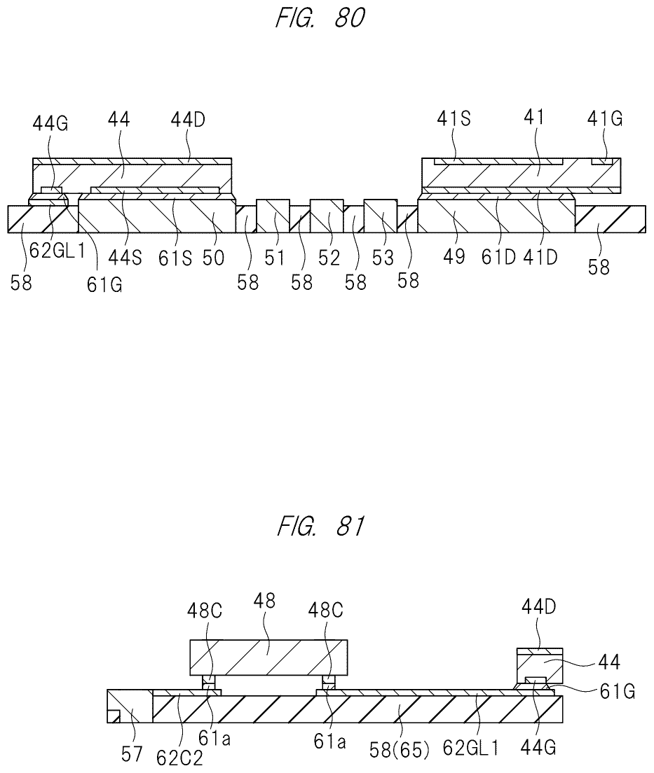

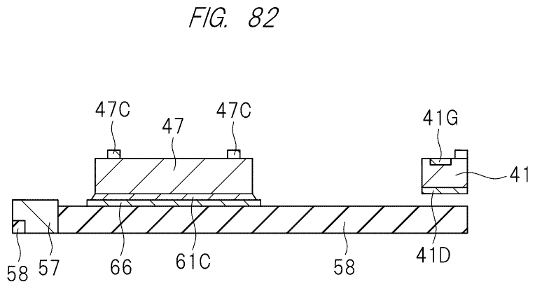

Next, a manufacturing process of the semiconductor device 1c according to the fourth embodiment will be described. FIG. 74 to FIG. 82 are cross-sectional views each showing a manufacturing step of the semiconductor device 1c according to the fourth embodiment. In FIG. 74 to FIG. 82, FIG. 74, FIG. 77, and FIG. 80 show the cross-section corresponding to FIG. 67 described above, FIG. 75, FIG. 78, and FIG. 81 show the cross-section corresponding to FIG. 70 described above, and FIG. 76, FIG. 79, and FIG. 82 show the cross-section corresponding to FIG. 71 described above.

First, a lead frame is prepared. In the case of the fourth embodiment, the lead frame includes a frame (not shown here), the die pads 49 and 50 connected to the frame, the output conductor portions 51, 52, and 53, and the plurality of leads 57, but does not include the gate connection conductor portion. Then, after forming the sealing portion 58 as shown in FIG. 42 and FIG. 43 of the second embodiment described above, the thickness of the sealing portion 58 is reduced by polishing the upper surface of the sealing portion 58. In this way, as shown in FIG. 74 to FIG. 76, the upper surfaces of the die pads 49 and 50, the output conductor portions 51, 52, and 53, and the plurality of leads 57 are exposed from the sealing portion 58.

Next, as shown in FIG. 77 to FIG. 79, a metal layer 70 is formed. The wirings 62GL1, 62GL2, 62GL3, and 62C2 and the conductor pattern 66 are formed of the metal layer 70 formed on the sealing portion 58. Further, the metal layer 70 is also formed on the die pads 49 and 50, the output conductor portions 51, 52, and 53, and the leads 57. Since this step can be performed in substantially the same manner as the step of forming the wirings 26 described in the first embodiment, the description thereof will be omitted here. In the following FIG. 80 to FIG. 82, for the sake of simplicity, the metal layer 70 formed on each of the die pads 49 and 50, the output conductor portions 51, 52, and 53, and the leads 57 is not shown separately, but is included in the die pads 49 and 50, the output conductor portions 51, 52, and 53, and the leads 57 (the same applies to FIG. 67 to FIG. 71 above).

Next, as shown in FIG. 80 to FIG. 82, a die bonding process is performed. In the die bonding process, the semiconductor chips 41, 42, and 43 are mounted on the die pad 49, the semiconductor chips 44, 45, and 46 are mounted on the die pad 50, and the semiconductor chips 47 and 48 are mounted on the sealing portion 58. The semiconductor chips 41, 42, and 43 are mounted such that the drain electrodes 41D, 42D, and 43D face the upper surface of the die pad 49, and the drain electrodes 41D, 42D, and 43D are electrically connected to the die pad 49 via the conductive bonding material 61D. The semiconductor chips 44, 45, and 46 are mounted such that the source electrodes 44S, 45S, and 46S face the upper surface of the die pad 50, and the source electrodes 44S, 45S, and 46S are electrically connected to the die pad 50 via the conductive bonding material 61S. The gate electrodes 44G, 45G, and 46G of the semiconductor chips 44, 45, and 46 are electrically connected to the wirings 62GL1, 62GL2, and 62GL3 via the conductive bonding material 61G such as solder. The semiconductor chip 47 is mounted on the upper surface of the conductor pattern 66 via the bonding material 61C such as solder such that the back surface of the semiconductor chip 47 faces the upper surface of the conductor pattern 66 (sealing portion 58). The semiconductor chip 48 is mounted on the upper surface of the sealing portion 58 such that the front surface of the semiconductor chip 48 (the main surface on the side where the electrodes 48C are formed) faces the upper surface of the sealing portion 58. Each of the plurality of electrodes 48C of the semiconductor chip 48 is electrically connected to any of the wirings 62GL1, 62GL2, 62GL3, and 62C2.

The subsequent steps are substantially the same as those in the second embodiment described above. Namely, as can be seen from FIG. 67 to FIG. 71, the sealing portion 59 is first formed to cover the semiconductor chips 41, 42, 43, 44, 45, 46, 47, and 48, and then holes are formed in the sealing portion 59 and the plug portions 63 are formed in the holes. Thereafter, the upper surface of the sealing portion 59 is polished to reduce the thickness of the sealing portion 59, whereby the upper surfaces of the electrodes 47C of the semiconductor chip 47 and the plug portions 63 are exposed from the upper surface of the sealing portion 59. Further, openings are formed in the sealing portion 59 so as to expose the source electrodes 41S, 42S, and 43S and the gate electrodes 41G, 42G, and 43G of the semiconductor chips 41, 42, and 43 and the drain electrodes 44D, 45D, and 46D of the semiconductor chips 44, 45, and 46. Thereafter, the wirings 62DS1, 62DS2, 62DS3, 62GH1, 62GH2, 62GH3, and 62C2 are formed. Further, the insulating layer 64 is formed on the upper surface of the sealing portion 59 so as to cover the wirings 62. Then, the semiconductor device 1c can be obtained by cutting between adjacent packages with a dicing blade.

In the fourth embodiment, the plug portion 63 is not required for electrically connecting the gate electrodes 41G, 42G, and 43G of the semiconductor chips 41, 42, and 43 and the electrodes 47C of the semiconductor chip 47, and the plug portion 63 is not required also for electrically connecting the gate electrodes 44G, 45G, and 46G of the semiconductor chips 44, 45, and 46 and the electrodes 48C of the semiconductor chip 48. Accordingly, the structure required for electrical connection between semiconductor chips can be simplified. Therefore, it is advantageous for the size reduction of the semiconductor device.

### Fifth Embodiment

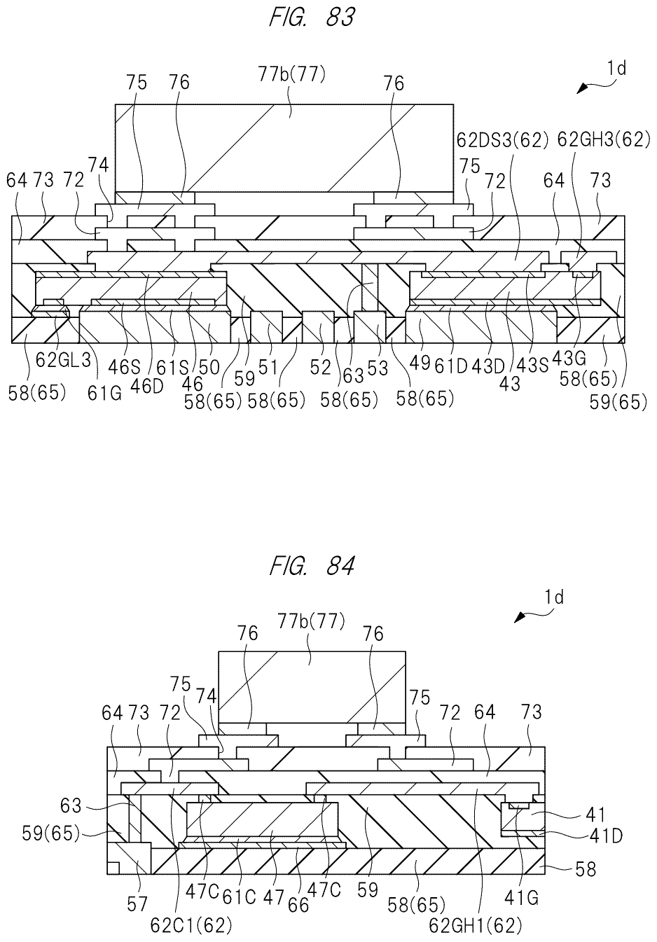

The fifth embodiment is a modification in which an upper layer wiring is further added to the semiconductor device 1c according to the fourth embodiment described above such that electronic components can be mounted on the semiconductor device. FIG. 83 and FIG. 84 are cross-sectional views of a semiconductor device 1d according to the fifth embodiment. FIG. 83 corresponds to FIG. 67 described above, and FIG. 84 corresponds to FIG. 71 described above.

Since the semiconductor device 1d according to the fifth embodiment is the same as the semiconductor device 1c according to the fourth embodiment regarding the structure below the insulating layer 64, the repetitive description thereof will be omitted here.

As shown in FIG. 83 and FIG. 84, in the semiconductor device 1d according to the fifth embodiment, one or more wiring layers are further formed on the insulating layer 64. In the case of FIG. 83 and FIG. 84, wirings 72 are formed on the insulating layer 64, an insulating layer 73 is formed on the insulating layer 64 so as to cover the wirings 72, and wirings 75 are formed on the insulating layer 73. The wiring 72 is electrically connected to the wiring 62 via an opening 71 (opening 71 that exposes the wiring 62) provided in the insulating layer 64. The wiring 75 is electrically connected to the wiring 72 via an opening 74 (opening 74 that exposes the wiring 72) provided in the insulating layer 73. An electronic component 77 is mounted on the semiconductor device 1d, that is, on the wiring 75 of the semiconductor device 1d. In the case of FIG. 83 and FIG. 84, electronic components 77a and 77b are mounted, but the number of electronic components to be mounted is not particularly limited. Electrodes of the electronic component 77 are electrically connected to the wirings 75 via a conductive bonding material 76 such as solder. In this way, the electronic component 77 can be electrically connected via the wiring 62 to any of the semiconductor chips 41, 42, 43, 44, 45, 46, 47, and 48 included in the semiconductor device 1d. As the electronic component 77, for example, a coil, a capacitor, and others can be used.

Since other electronic components can be mounted on the semiconductor device in the fifth embodiment, there is no need to secure the space necessary for mounting the electronic components on the mounting board or the like on which the semiconductor device is mounted.

Although the semiconductor device 1d shown in FIG. 83 and FIG. 84 is based on the semiconductor device 1c according to the fourth embodiment, it can also be based on the semiconductor devices according to the embodiments other than the fourth embodiment.

### Sixth Embodiment

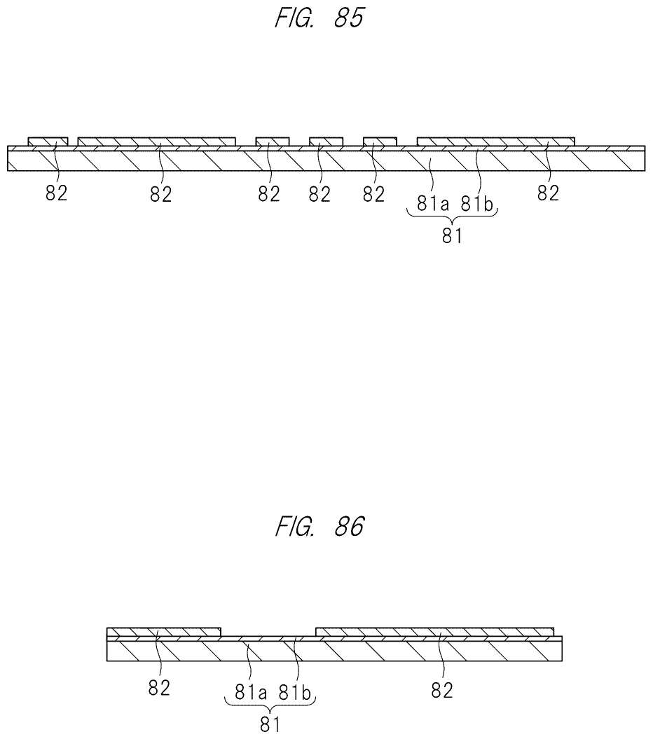

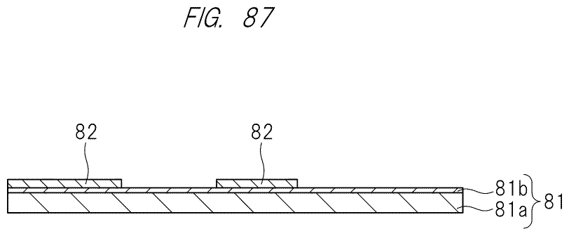

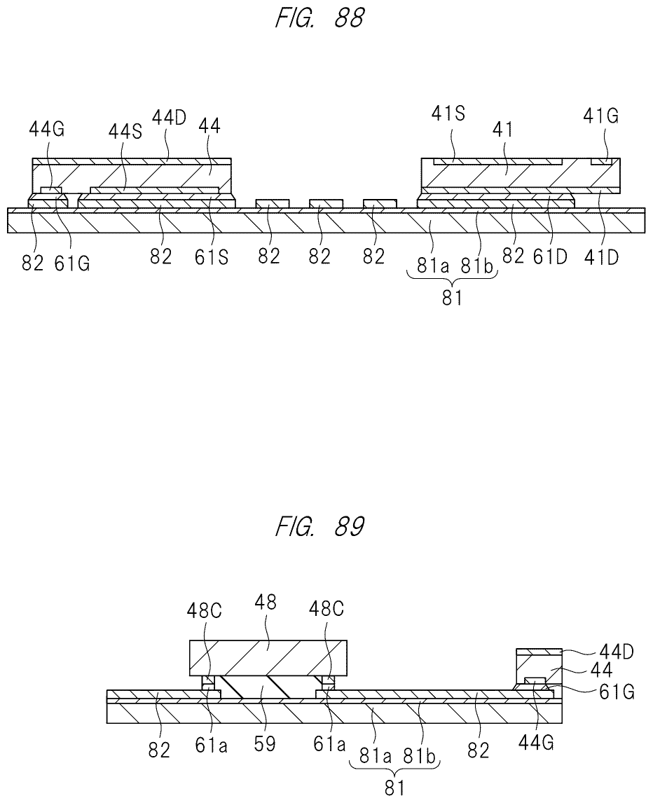

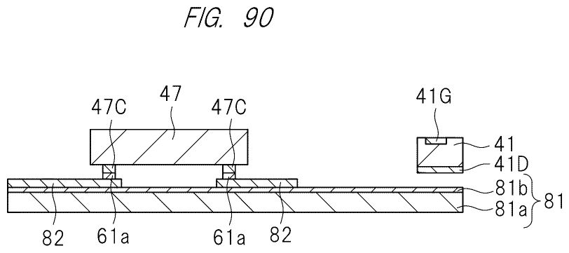

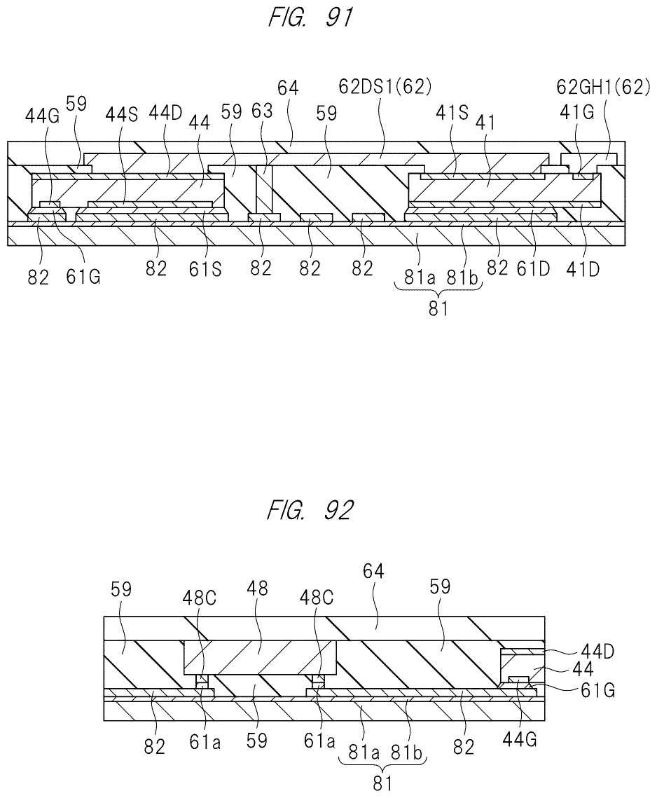

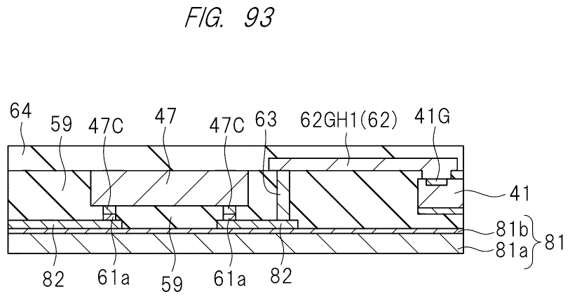

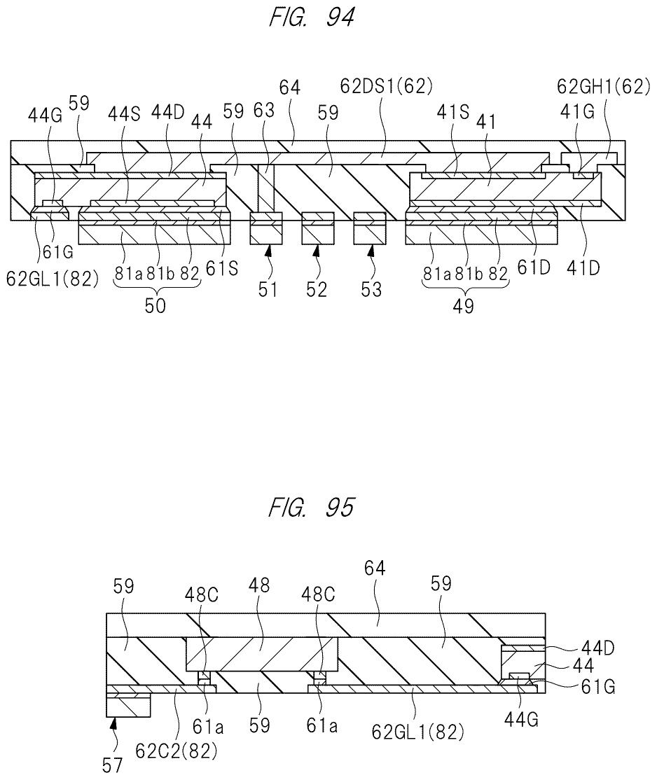

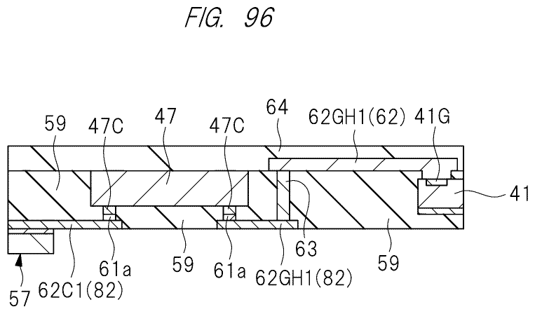

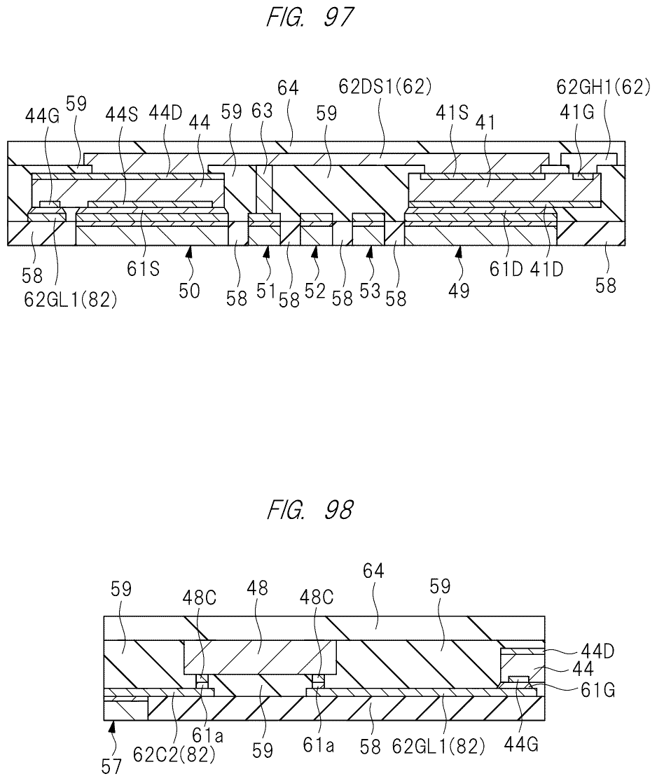

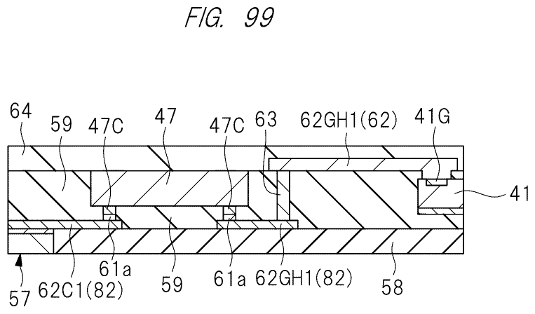

In the foregoing, embodiments using a lead frame have been described, but the case where the semiconductor device is manufactured without using the lead frame will be described in the sixth embodiment. FIG. 85 to FIG. 99 are cross-sectional views each showing a manufacturing step of the semiconductor device according to the sixth embodiment. In FIG. 85 to FIG. 99, FIG. 85, FIG. 88, FIG. 91, FIG. 94, and FIG. 97 show the cross-section corresponding to FIG. 67 described above, FIG. 86, FIG. 89, FIG. 92, FIG. 95, and FIG. 98 show the cross-section corresponding to FIG. 70 described above, and FIG. 87, FIG. 90, FIG. 93, FIG. 96, and FIG. 99 show the cross-section corresponding to FIG. 71 described above.

First, as shown in FIG. 85 to FIG. 87, a metal plate 81 is prepared. The metal plate 81 is composed of a metal layer (metal substrate) 81a serving as a base and a metal layer 81b formed on an upper surface of the metal layer 81a. The metal layer 81b is thinner than the metal layer 81a. Also, the metal layer 81a and the metal layer 81b are made of metal materials different from each other. The metal layer 81b functions as an etching stopper layer when etching the metal layer 81a later.

Next, a metal pattern 82 is formed on an upper surface of the metal plate 81, that is, on the metal layer 81b constituting the metal plate 81. Since the step of forming the metal pattern 82 can be performed in substantially the same manner as the step of forming the wirings 26 described in the first embodiment, the description thereof will be omitted here.

The metal pattern 82 is preferably made of the same metal material as the metal layer 81a. For example, the metal layer 81a and the metal pattern 82 are both made of copper or a copper alloy. The metal layer 81b can be, for example, a titanium layer. The metal layer 81a is preferably thicker than the metal pattern 82.

The metal pattern 82 includes parts to be the die pads 49 and 50, parts to be the output conductor portions 51 to 53, parts to be the leads 57, and parts to be the wirings 62.

Next, as shown in FIG. 88 to FIG. 90, a die bonding process is performed.

In the die bonding process, the drain electrodes 41D, 42D, and 43D of the semiconductor chips 41, 42, and 43 are connected to the part of the metal pattern 82 to be the die pad 49 via the conductive bonding material 61D such as solder. Also, the source electrodes 44S, 45S, and 46S of the semiconductor chips 44, 45, and 46 are connected to the part of the metal pattern 82 to be the die pad 50 via the conductive bonding material 61S such as solder. Further, the gate electrodes 44G, 45G, and 46G of the semiconductor chips 44, 45, and 46 are connected to the parts of the metal pattern 82 to be the wirings 62GL1, 62GL2, and 62GL3 via the conductive bonding material 61G such as solder.

Also, the semiconductor chips 47 and 48 are mounted such that surfaces of the semiconductor chips 47 and 48 (main surfaces on the side where the electrodes 47C and 48C are formed) face the metal plate 81, whereby the electrodes 47C are electrically connected to the parts of the metal pattern 82 to be the wirings 62GH1, 62GH2, 62GH3, and 62C1 via the conductive bonding material 61a such as solder and the electrodes 48C are electrically connected to the parts of the metal pattern 82 to be the wirings 62GL1, 62GL2, 62GL3, and 62C2 via the conductive bonding material 61a such as solder.

The sixth embodiment is almost the same as the fourth embodiment described above after the die bonding process up to the step of forming the insulating layer 64. Namely, as can be seen from FIG. 91 to FIG. 93, the sealing portion 59 is first formed so as to cover the semiconductor chips 41, 42, 43, 44, 45, 46, 47, and 48, and then holes are formed in the sealing portion 59 and the plug portions 63 are formed in the holes. Then, after polishing the upper surface of the sealing portion 59 to reduce the thickness of the sealing portion 59, openings are formed in the sealing portion 59 so as to expose the source electrodes 41S, 42S, and 43S and the gate electrodes 41G, 42G, and 43G of the semiconductor chips 41, 42, and 43 and the drain electrodes 44D, 45D, and 46D of the semiconductor chips 44, 45, and 46 from the openings. Thereafter, the wirings 62 are formed. The wirings 62 include the wirings 62DS1, 62DS2, 62DS3, 62GH1, 62GH2, and 62GH3. The method of forming the wirings 62 is the same as those in the fourth embodiment and others described above. Then, the insulating layer 64 is formed on the upper surface of the sealing portion 59 so as to cover the wirings 62. This stage corresponds to FIG. 91 to FIG. 93.

Next, a resist pattern (not shown) is formed on the lower surface of the metal plate 81, and then a part of the metal plate 81 not covered with the resist pattern is removed by etching from the lower surface side of the metal plate 81. Thereafter, the resist pattern is removed, and this stage corresponds to FIG. 94 to FIG. 96. In this etching, the metal layer 81a is first etched using the metal layer 81b as an etching stopper, and then the exposed metal layer 81b is etched. In this way, the metal plate 81 is partially removed, and the remaining metal plate 81 and the metal pattern 82 thereon constitute the die pad 49, the die pad 50, the output conductor portions 51, 52, and 53, and the leads 57. No metal plate 81 remains under the parts of the wirings 62GH1 to 62GH3, the wirings 62GL1 to 62GL1, and the wirings 62C1 and 62C2 where the leads 57 are not formed.

Next, as shown in FIG. 97 to FIG. 99, the sealing portion 58 made of an insulator is formed. The sealing portion 58 is formed so as to cover the side surfaces of the die pads 49 and 50, the output conductor portions 51, 52, and 53, and the leads 57, the lower surfaces of the wirings 62GL1, 62GL2, 62GL3, 62GH1, 62GH2, 62GH3, 62C1, and 62C2, and the exposed lower surface of the sealing portion 59. On the lower surface of the sealing portion 58, the lower surfaces of the die pads 49 and 50, the output conductor portions 51, 52, and 53, and the leads 57 are exposed. Alternatively, these lower surfaces may be exposed by polishing the sealing portion 58 after forming the sealing portion 58 so as to cover these lower surfaces.

In the sixth embodiment, both the semiconductor chips 47 and 48 are connected face down. The wirings 62GH1, 62GH2, and 62GH3 that electrically connect the gate electrodes 41G, 42G, and 43G of the semiconductor chips 41, 42, and 43 to the electrodes 47C of the semiconductor chip 47 are composed of the wirings 62 and the metal pattern 82, and these are electrically connected via the plug portions 63. For example, one end of the wiring 62GH1 formed of the wiring 62 is connected to the gate electrode 41G of the semiconductor chip 41 and the other end thereof is connected to the plug portion 63, and one end of the wiring 62GH1 formed of the metal pattern 82 is connected to the electrode 47C of the semiconductor chip 47 and the other end thereof is connected to the plug portion 63. The same applies to the wiring 62GH2 and the wiring 62GH3.

Further, as a modification of the sixth embodiment, one or both of the semiconductor chips 47 and 48 may be bonded face up.

### Seventh Embodiment

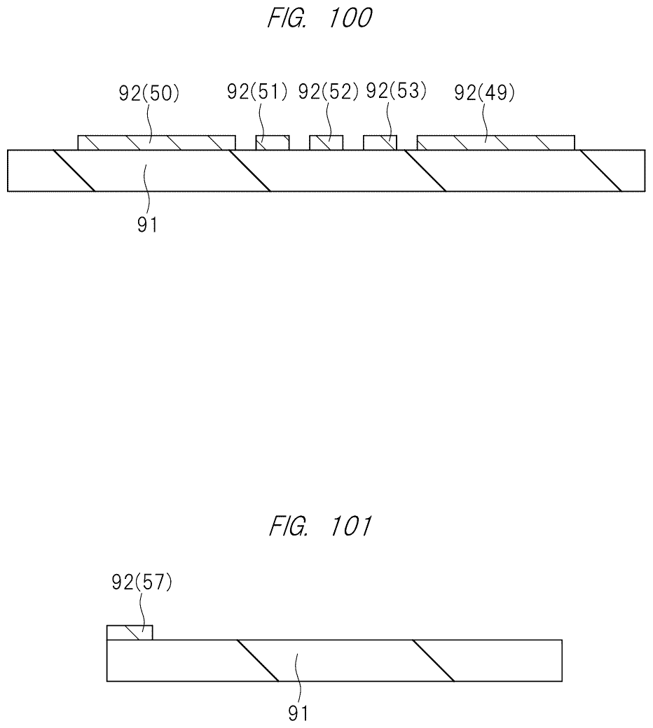

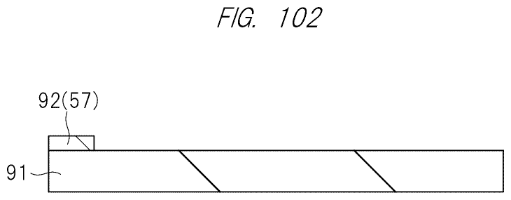

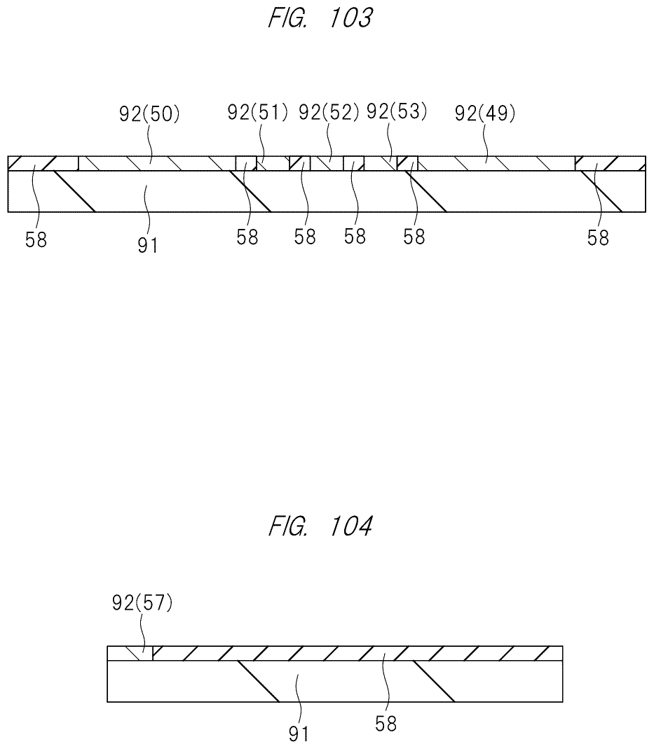

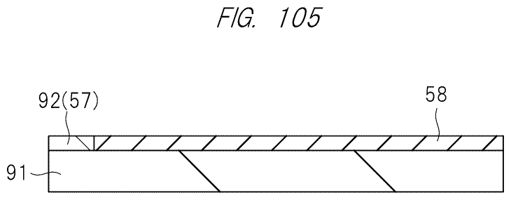

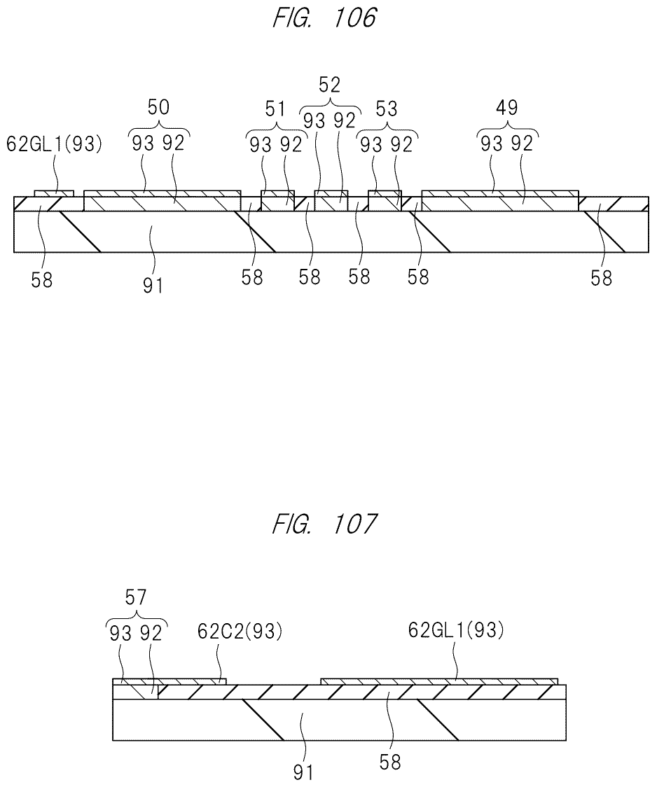

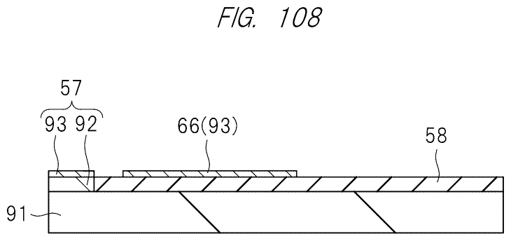

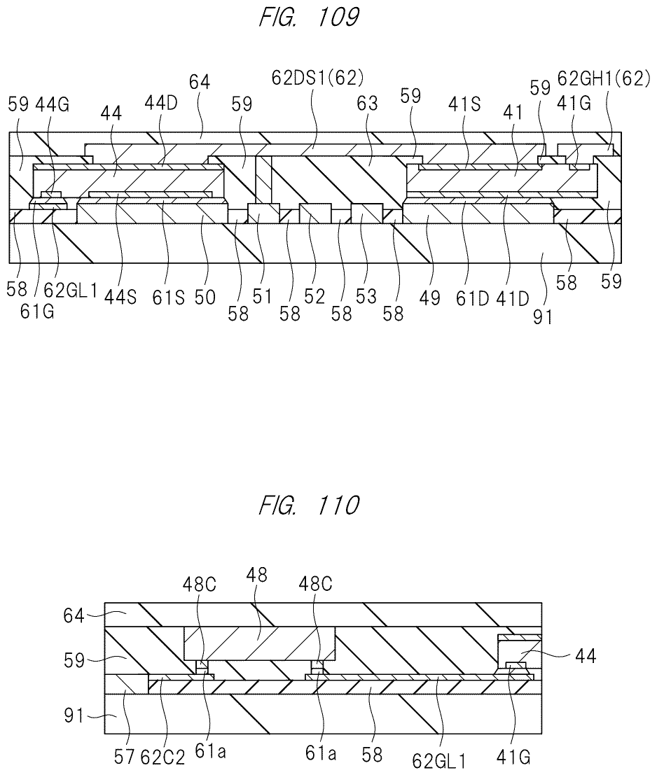

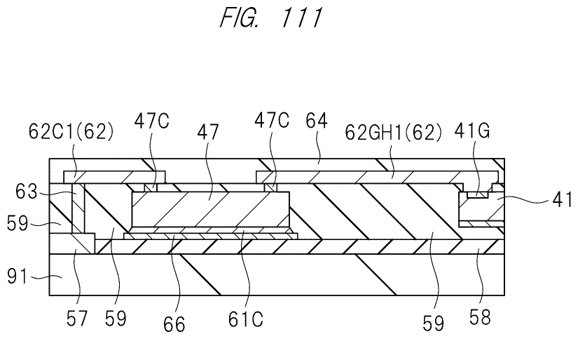

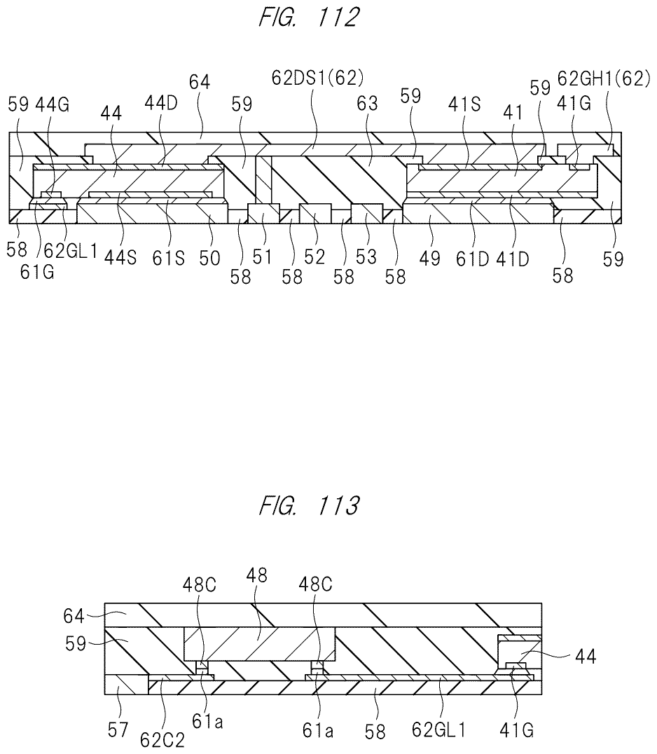

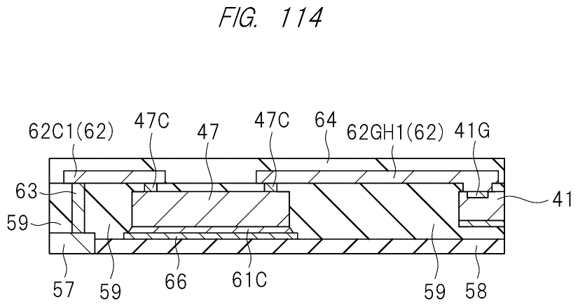

In the seventh embodiment as well, a semiconductor device that does not use a lead frame will be described. FIG. 100 to FIG. 114 are cross-sectional views each showing a manufacturing step of the semiconductor device according to the seventh embodiment. In FIG. 100 to FIG. 114, FIG. 100, FIG. 103, FIG. 106, FIG. 109, and FIG. 112 show the cross-section corresponding to FIG. 67 described above, FIG. 101, FIG. 104, FIG. 107, FIG. 110, and FIG. 113 show the cross-section corresponding to FIG. 70 described above, and FIG. 102, FIG. 105, FIG. 108, FIG. 111, and FIG. 114 show the cross-section corresponding to FIG. 71 described above.

First, as shown in FIG. 100 to FIG. 102, an insulating substrate 91 is prepared. For example, a glass substrate can be used as the insulating substrate 91. A metal layer for seed layer may be formed on the entire upper surface of the insulating substrate 91, if necessary.

Next, as shown in FIG. 100 to FIG. 102, a metal pattern 92 is formed on the insulating substrate 91. For example, the metal pattern 92 is formed by forming a resist pattern (not shown) on the insulating substrate 91 and then forming a metal layer by electrolytic plating on a region of the upper surface of the insulating substrate 91 that is not covered with the resist pattern. The metal pattern 92 is made of, for example, copper or a copper alloy. Thereafter, the resist pattern is removed. The metal pattern 92 includes parts to be the die pads 49 and 50, parts to be the output conductor portions 51 to 53, and parts to be the leads 57.

Next, by forming the sealing portion 58 so as to cover the metal pattern 92 and then polishing the upper surface of the sealing portion 58, the upper surface of the metal pattern 92 is exposed from the sealing portion 58 as shown in FIG. 103 to FIG. 105.

Next, as shown in FIG. 106 to FIG. 108, a metal layer 93 is formed. This step can be performed in the same manner as the step of forming the metal layer 70 in the fourth embodiment described above. The metal layer 93 formed on the sealing portion 58 forms the wirings 62GL1, 62GL2, 62GL3, and 62C2 and the conductor pattern 66. Further, the metal layer 93 is also formed on the metal pattern 92. The metal pattern 92 and the metal layer 93 thereon form the die pads 49 and 50, the output conductor portions 51, 52, and 53, and the leads 57. The metal pattern 92 and the metal layer 93 constituting the die pads 49 and 50, the output conductor portions 51, 52, and 53, and the leads 57 are not shown separately, but are shown integrally for the sake of simplicity in following FIG. 109 to FIG. 114.

Next, in the same manner as in the fourth embodiment described above, the die bonding process to the step of forming the insulating layer 64 are performed to obtain the structure shown in FIG. 109 to FIG. 111. Since the steps during that in the seventh embodiment are almost the same as those in the fourth embodiment described above, the repetitive description thereof will be omitted here.

Next, as shown in FIG. 112 to FIG. 114, the insulating substrate 91 and the structure thereon are separated. If the metal layer for seed layer described above has been formed, it can be removed by etching after this separation step. In this way, the semiconductor device can be manufactured.

The manufacturing process according to the sixth embodiment can be applied not only to the fourth embodiment described above but also to the other embodiments.

In the foregoing, the invention made by the inventor of this application has been specifically described based on the embodiments, but the present invention is not limited to these embodiments, and can be modified in various ways within the range not departing from the gist thereof.

### REFERENCE SIGNS LIST

1, 1a, 1b, 1c, 1d semiconductor device
2, 3, 4 semiconductor chip
2D, 3D drain electrode
2G, 3G gate electrode
2S, 3S source electrode
4C electrode
5, 6, 7 die pad
6G gate connection conductor portion
8 lead
9 sealing portion
10C, 10D, 10G, 10S bonding material
12, 13 power MOSFET
14 control circuit
21 hole
22 plug portion
23 opening
24a, 24b metal film
25 resist pattern
26, 26DS, 26GL, 26GH, 26C1, 26C2, 26C3 wiring
27 insulating layer
28 insulator portion
29 opening
30, 30C, 30DS wiring
31 electronic component
41, 42, 43, 44, 45, 46, 47, 48 semiconductor chip
41a, 42a, 43a, 44a, 45a, 46a power MOSFET
47a, 48a control circuit
41D, 42D, 43D, 44D, 45D, 46D drain electrode
41G, 42G, 43G, 44G, 45G, 46G gate electrode
41S, 42S, 43S, 44S, 45S, 46S source electrode
47C, 48C electrode
49, 50 die pad
51, 52, 53 output conductor portion
54, 55, 56 gate connection conductor portion
57 lead
58, 59 sealing portion
61a, 61C, 61D, 61G, 61S bonding material
62, 62C1, 62C2, 62DS1, 62DS2, 62DS3, 62GH1, 62GH2, 62GH3, 62GL1, 62GL2, 62GL3 wiring
63 plug portion
64 insulating layer
65 insulator portion
71 opening
72 wiring
73 insulating layer
74 opening
75 wiring
76 bonding material
77 electronic component
81 metal plate
81a, 81b metal layer
82 metal pattern
91 insulating substrate
92 metal pattern
93 metal layer

1. A semiconductor device comprising:
a first chip mounting portion;
a second chip mounting portion;
a first semiconductor chip having a main surface and a back surface on a side opposite to the main surface and mounted on the first chip mounting portion;
a second semiconductor chip having a main surface and a back surface on a side opposite to the main surface and mounted on the second chip mounting portion; and
an insulator portion configured to seal at least a part of the first chip mounting portion, at least a part of the second chip mounting portion, the first semiconductor chip, and the second semiconductor chip,
wherein the first semiconductor chip has a source electrode formed on a side of the main surface of the first semiconductor chip and a drain electrode formed on a side of the back surface of the first semiconductor chip, and is mounted on the first chip mounting portion such that the drain electrode faces the first chip mounting portion,
wherein the second semiconductor chip has a source electrode formed on a side of the main surface of the second semiconductor chip and a drain electrode formed on a side of the back surface of the second semiconductor chip, and is mounted on the second chip mounting portion such that the source electrode faces the second chip mounting portion, and
wherein a first wiring configured to electrically connect the source electrode of the first semiconductor chip and the drain electrode of the second semiconductor chip is formed in the insulator portion.

2. The semiconductor device according to claim 1, further comprising a third semiconductor chip sealed with the insulator portion and having a plurality of electrodes,
wherein the first semiconductor chip further has a gate electrode formed on the side of the main surface of the first semiconductor chip,
wherein the second semiconductor chip further has a gate electrode formed on the side of the main surface of the second semiconductor chip, and
wherein a second wiring configured to electrically connect a first electrode of the plurality of electrodes of the third semiconductor chip and the gate electrode of the first semiconductor chip is formed in the insulator portion.

3. The semiconductor device according to claim 2,
wherein the first wiring and the second wiring are formed in a same layer.

4. The semiconductor device according to claim 2, further comprising a third chip mounting portion sealed at least partially with the insulator portion and configured to mount the third semiconductor chip.

5. The semiconductor device according to claim 2,
wherein a third wiring configured to electrically connect a second electrode of the plurality of electrodes of the third semiconductor chip and the gate electrode of the second semiconductor chip is formed in the insulator portion.

6. The semiconductor device according to claim 5, further comprising:
a gate connection conductor portion sealed with the insulator portion and configured to face and electrically connected to the gate electrode of the second semiconductor chip; and
a conductive first plug portion arranged between the gate connection conductor portion and the third wiring and configured to electrically connect the gate connection conductor portion and the third wiring,
wherein the gate electrode of the second semiconductor chip is electrically connected to the second electrode of the third semiconductor chip via the gate connection conductor portion, the first plug portion, and the third wiring.

7. The semiconductor device according to claim 6,
wherein the first wiring and the third wiring are formed in a same layer.

8. The semiconductor device according to claim 2, further comprising a lead sealed at least partially with the insulator portion,
wherein a fourth wiring configured to electrically connect a third electrode of the plurality of electrodes of the third semiconductor chip and the lead is formed in the insulator portion.

9. The semiconductor device according to claim 8, further comprising a conductive second plug portion arranged between the lead and the fourth wiring and configured to electrically connect the lead and the fourth wiring,
wherein the lead is electrically connected to the third electrode of the third semiconductor chip via the second plug portion and the fourth wiring.

10. The semiconductor device according to claim 9,
wherein the first wiring and the fourth wiring are formed in a same layer.

11. The semiconductor device according to claim 2,
wherein the first chip mounting portion and the second chip mounting portion are exposed on a back surface of the insulator portion.

12. The semiconductor device according to claim 2,
wherein a control circuit configured to control the first semiconductor chip and the second semiconductor chip is formed in the third semiconductor chip.

13. The semiconductor device according to claim 12,
wherein a field effect transistor for high side switch is formed in the first semiconductor chip, and
wherein a field effect transistor for low side switch is formed in the second semiconductor chip.

14. The semiconductor device according to claim 1, further comprising:
a fourth semiconductor chip sealed with the insulator portion, having a main surface and a back surface on a side opposite to the main surface, and mounted on the first chip mounting portion; and
a fifth semiconductor chip sealed with the insulator portion, having a main surface and a back surface on a side opposite to the main surface, and mounted on the second chip mounting portion,
wherein the fourth semiconductor chip has a source electrode formed on a side of the main surface of the fourth semiconductor chip and a drain electrode formed on a side of the back surface of the fourth semiconductor chip, and is mounted on the first chip mounting portion such that the drain electrode faces the first chip mounting portion,
wherein the fifth semiconductor chip has a source electrode formed on a side of the main surface of the fifth semiconductor chip and a drain electrode formed on a side of the back surface of the fifth semiconductor chip, and is mounted on the second chip mounting portion such that the source electrode faces the second chip mounting portion, and
wherein a fifth wiring configured to electrically connect the source electrode of the fourth semiconductor chip and the drain electrode of the fifth semiconductor chip is formed in the insulator portion.

15. The semiconductor device according to claim 14, further comprising:
a sixth semiconductor chip sealed with the insulator portion, having a main surface and a back surface on a side opposite to the main surface, and mounted on the first chip mounting portion; and
a seventh semiconductor chip sealed with the insulator portion, having a main surface and a back surface on a side opposite to the main surface, and mounted on the second chip mounting portion,
wherein the sixth semiconductor chip has a source electrode formed on a side of the main surface of the sixth semiconductor chip and a drain electrode formed on a side of the back surface of the sixth semiconductor chip, and is mounted on the first chip mounting portion such that the drain electrode faces the first chip mounting portion,
wherein the seventh semiconductor chip has a source electrode formed on a side of the main surface of the seventh semiconductor chip and a drain electrode formed on a side of the back surface of the seventh semiconductor chip, and is mounted on the second chip mounting portion such that the source electrode faces the second chip mounting portion, and
wherein a sixth wiring configured to electrically connect the source electrode of the sixth semiconductor chip and the drain electrode of the seventh semiconductor chip is formed in the insulator portion.

16. The semiconductor device according to claim 15, further comprising:
an eighth semiconductor chip sealed with the insulator portion and having a plurality of electrodes; and
a ninth semiconductor chip sealed with the insulator portion and having a plurality of electrodes,
wherein the eighth semiconductor chip includes a first control circuit configured to control the first semiconductor chip, the fourth semiconductor chip, and the sixth semiconductor chip, and
wherein the ninth semiconductor chip includes a second control circuit configured to control the second semiconductor chip, the fifth semiconductor chip, and the eighth semiconductor chip.
